(19) United States
(12) Patent Application Publication
(10) Pub. No.: US 2024/0421220 A1
(43) Pub. Date: Dec. 19, 2024

(54) NITRIDE SEMICONDUCTOR DEVICE

(71) Applicant: ROHM CO., LTD., Kyoto-shi (JP)

(72) Inventors: Manabu YANAGIHARA, Kyoto-shi (JP); Ryoichi MAKINO, Kyoto-shi (JP)

(73) Assignee: ROHM CO., LTD., Kyoto-shi (JP)

(21) Appl. No.: 18/742,179

(22) Filed: Jun. 13, 2024

(30) Foreign Application Priority Data
Jun. 19, 2023 (JP) 2023-100205

(51) Int. Cl. H01L 29/778; H01L 29/20; H01L 29/423; H01L 29/45; H01L 29/47; H01L 29/66

(52) U.S. Cl. CPC H01L 29/7787; H01L 29/2003; H01L 29/42316; H01L 29/452; H01L 29/47; H01L 29/66462

(57) ABSTRACT

A nitride semiconductor device includes an electron transit layer, an electron supply layer, a gate layer, a first gate electrode, a source electrode, a drain electrode, and a second gate electrode. The second gate electrode is made of a material different from the first gate electrode. The first gate electrode and the second gate electrode are in contact with an upper surface of the gate layer. A second contact area, which is a contact area between the second gate electrode and the gate layer, is smaller than a first contact area, which is a contact area between the first gate electrode and the gate layer.

### CROSS-REFERENCE TO RELATED APPLICATION

This application is based upon and claims the benefit of priority from prior Japanese Patent Application No. JP2023-100205, filed on Jun. 19, 2023, the entire contents of which are incorporated herein by reference.

### BACKGROUND

### 1. Field

The present disclosure relates to a nitride semiconductor device.

### 2. Description of Related Art

At present, a high electron mobility transistor (HEMT) using a group III nitride semiconductor (hereinafter, it may be simply referred to as a “nitride semiconductor”) such as gallium nitride (GaN) has been commercialized. The HEMT uses a two-dimensional electron gas (2DEG) formed near an interface of a semiconductor heterojunction as a conductive path (channel). A power device using the HEMT is recognized as a device that enables low on-resistance and high speed and high frequency operation as compared with a typical silicon (Si) power device.

For example, a nitride semiconductor device described in Japanese Laid-Open Patent Publication No. 2017-73506 includes an electron transit layer including a gallium nitride (GaN) layer and an electron supply layer including an aluminum gallium nitride (AlGaN) layer. The 2DEG is formed in the electron transit layer near the interface of the heterojunction between the electron transit layer and the electron supply layer.

Further, in the nitride semiconductor device of Japanese Laid-Open Patent Publication No. 2017-73506, a gate layer (for example, a p-type GaN layer) containing an acceptor impurity is provided on the electron supply layer, and a gate electrode is disposed on the gate layer. In this configuration, in a region immediately below the gate layer, the gate layer raises a band energy of the conduction band near the heterojunction interface between the electron transit layer and the electron supply layer, so that a channel immediately below the gate layer disappears, and a normally-off operation is achieved.

### BRIEF DESCRIPTION OF THE DRAWINGS

FIG. 1 is a schematic plan view of an exemplary nitride semiconductor device according to a first embodiment.

FIG. 2 is a schematic cross-sectional view taken along line 2-2 in FIG. 1.

FIG. 3 is a schematic cross-sectional view taken along line 3-3 in FIG. 1.

FIG. 4 is a schematic cross-sectional view taken along line 2-2, illustrating one example of a method for manufacturing the nitride semiconductor device.

FIG. 5 is a schematic cross-sectional view taken along line 3-3, illustrating one example of the method for manufacturing the nitride semiconductor device.

FIG. 6 is a schematic cross-sectional view taken along line 2-2, illustrating one example of the method for manufacturing the nitride semiconductor device, which is subsequent to FIG. 4.

FIG. 7 is a schematic cross-sectional view taken along line 3-3, illustrating one example of the method for manufacturing the nitride semiconductor device, which is subsequent to FIG. 5.

FIG. 8 is a schematic cross-sectional view taken along line 2-2, illustrating one example of the method for manufacturing the nitride semiconductor device, which is subsequent to FIG. 6.

FIG. 9 is a schematic cross-sectional view taken along line 3-3, illustrating one example of the method for manufacturing the nitride semiconductor device, which is subsequent to FIG. 7.

FIG. 10 is a schematic cross-sectional view taken along line 2-2, illustrating one example of the method for manufacturing the nitride semiconductor device, which is subsequent to FIG. 8.

FIG. 11 is a schematic cross-sectional view taken along line 3-3, illustrating one example of the method for manufacturing the nitride semiconductor device, which is subsequent to FIG. 9.

FIG. 12 is a schematic cross-sectional view taken along line 2-2, illustrating one example of the method for manufacturing the nitride semiconductor device, which is subsequent to FIG. 10.

FIG. 13 is a schematic cross-sectional view taken along line 3-3, illustrating one example of the method for manufacturing the nitride semiconductor device, which is subsequent to FIG. 11.

FIG. 14 is an equivalent circuit diagram schematically illustrating the nitride semiconductor device.

FIG. 15 is a schematic plan view illustrating a modification of the nitride semiconductor device of the first embodiment.

FIG. 16 is a schematic end view taken along line 16-16 in FIG. 15.

FIG. 17 is a schematic end view taken along line 17-17 in FIG. 15.

FIG. 18 is a schematic plan view illustrating a modification of the nitride semiconductor device of the first embodiment.

FIG. 19 is a schematic cross-sectional view taken along line 19-19 in FIG. 18.

FIG. 20 is a schematic plan view of an exemplary nitride semiconductor device according to a second embodiment.

FIG. 21 is a schematic cross-sectional view taken along line 21-21 in FIG. 20.

FIG. 22 is a schematic cross-sectional view taken along line 22-22 in FIG. 20.

FIG. 23 is a schematic cross-sectional view taken along line 21-21, illustrating one example of the method for manufacturing the nitride semiconductor device.

FIG. 24 is a schematic cross-sectional view taken along line 22-22, illustrating one example of the method for manufacturing the nitride semiconductor device.

FIG. 25 is a schematic cross-sectional view taken along line 21-21, illustrating one example of the method for manufacturing the nitride semiconductor device, which is subsequent to FIG. 23.

FIG. 26 is a schematic cross-sectional view taken along line 22-22, illustrating one example of the method for manufacturing the nitride semiconductor device, which is subsequent to FIG. 24.

FIG. 27 is a schematic cross-sectional view taken along line 21-21, illustrating one example of the method for manufacturing the nitride semiconductor device, which is subsequent to FIG. 25.

FIG. 28 is a schematic cross-sectional view taken along line 22-22, illustrating one example of the method for manufacturing the nitride semiconductor device, which is subsequent to FIG. 26.

FIG. 29 is a schematic cross-sectional view taken along line 21-21, illustrating one example of the method for manufacturing the nitride semiconductor device, which is subsequent to FIG. 27.

FIG. 30 is a schematic cross-sectional view taken along line 22-22, illustrating one example of the method for manufacturing the nitride semiconductor device, which is subsequent to FIG. 28.

FIG. 31 is a schematic cross-sectional view taken along line 21-21, illustrating one example of the method for manufacturing the nitride semiconductor device, which is subsequent to FIG. 29.

FIG. 32 is a schematic cross-sectional view taken along line 22-22, illustrating one example of the method for manufacturing the nitride semiconductor device, which is subsequent to FIG. 30.

FIG. 33 is a schematic cross-sectional view taken along line 21-21, illustrating one example of the method for manufacturing the nitride semiconductor device, which is subsequent to FIG. 31.

FIG. 34 is a schematic cross-sectional view taken along line 22-22, illustrating one example of the method for manufacturing the nitride semiconductor device, which is subsequent to FIG. 32.

FIG. 35 is a schematic plan view illustrating a modification of the nitride semiconductor device of the second embodiment.

FIG. 36 is a schematic end view taken along line 36-36 in FIG. 35.

FIG. 37 is a schematic end view taken along line 37-37 in FIG. 35.

FIG. 38 is a schematic cross-sectional view illustrating a modification of the gate layer.

FIG. 39 is a schematic cross-sectional view illustrating a modification of a recess region.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

This description provides a comprehensive understanding of the methods, apparatuses, and/or systems described. Modifications and equivalents of the methods, apparatuses, and/or systems described are apparent to one of ordinary skill in the art. Sequences of operations are exemplary, and may be changed as apparent to one of ordinary skill in the art, except for operations necessarily occurring in a certain order. Descriptions of functions and constructions that are well known to one of ordinary skill in the art may be omitted.

Exemplary embodiments may have different forms, and are not limited to the examples described. However, the examples described are thorough and complete, and convey the full scope of the disclosure to one of ordinary skill in the art.

Hereinafter, embodiments of a nitride semiconductor device in the present disclosure will be described with reference to the accompanying drawings.

For simplicity and clarity of illustration, components shown in the drawings are not necessarily drawn to scale. Also, to facilitate understanding, hatching lines may be omitted in cross-sectional views. The accompanying drawings are merely illustrative of embodiments of the disclosure and should not be considered as limiting the disclosure.

This detailed description provides a comprehensive understanding of the methods, apparatuses, and/or systems described. Exemplary embodiments may have different forms, and are not limited to the examples described.

### First Embodiment

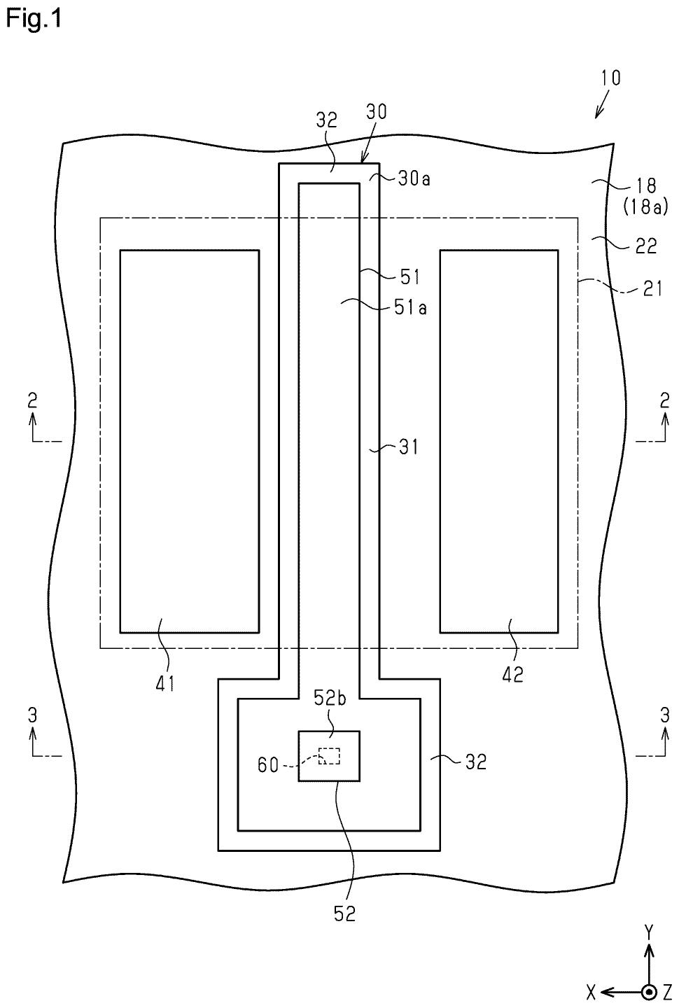

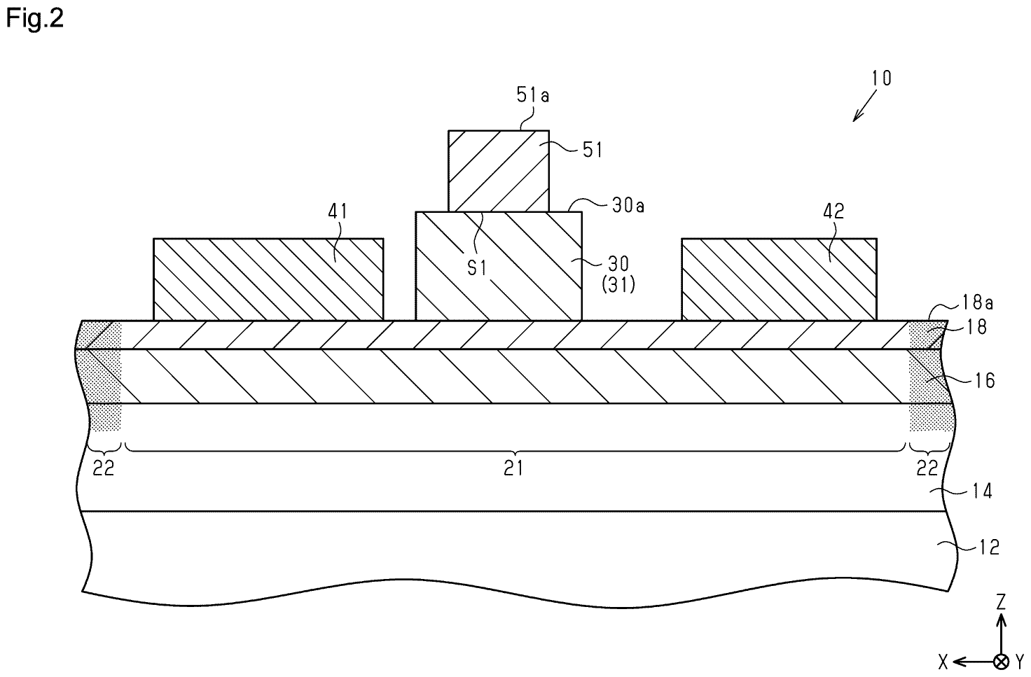

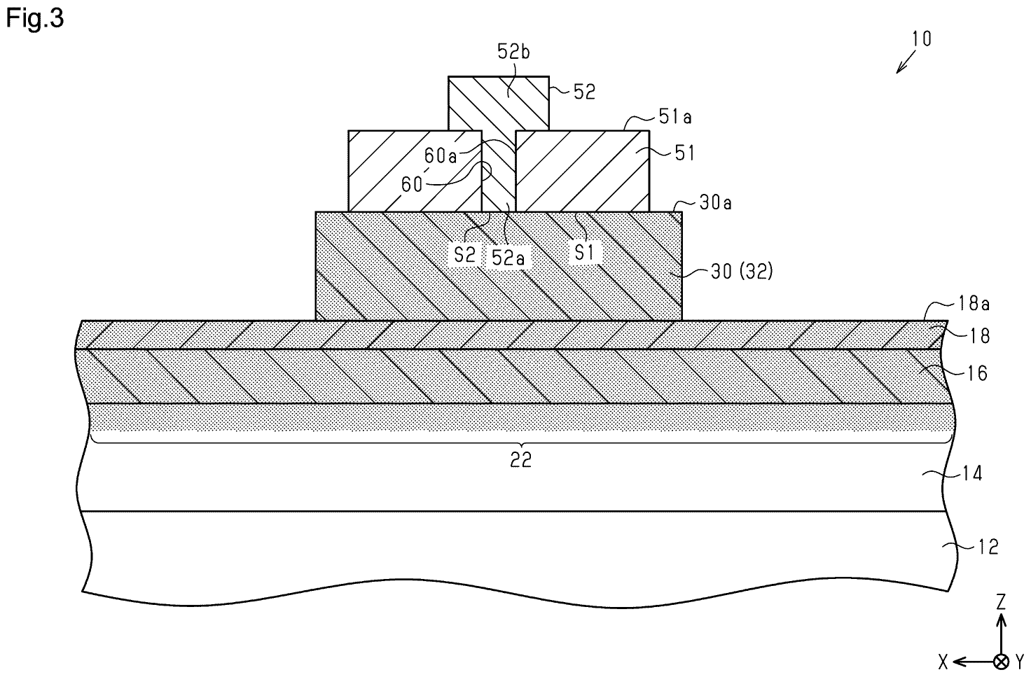

FIG. 1 is a schematic plan view of an exemplary nitride semiconductor device 10 according to a first embodiment. FIG. 2 is a schematic cross-sectional view taken along line 2-2 in FIG. 1. FIG. 3 is a schematic cross-sectional view taken along line 3-3 in FIG. 1. As one example of the nitride semiconductor device 10, a high electron mobility transistor (HEMT) using gallium nitride (GaN) will be described.

### Schematic Structure of Nitride Semiconductor Device 10

As illustrated in FIG. 2, the nitride semiconductor device 10 includes a semiconductor substrate 12, a buffer layer 14 formed on the semiconductor substrate 12, and an electron transit layer 16 formed on the buffer layer 14. The nitride semiconductor device 10 includes an electron supply layer 18 formed on the electron transit layer 16 and a gate layer 30 formed on the electron supply layer 18.

The semiconductor substrate 12 may be made of silicon (Si), silicon carbide (SiC), GaN, sapphire, or other substrate materials. In one example, the semiconductor substrate 12 may be a conductive Si substrate. The thickness of the semiconductor substrate 12 may be, for example, in a range of 200 m to 1500 m. The Z-axis direction, where the X, Y, and Z axes are orthogonal to each other, is a thickness direction of the semiconductor substrate 12. The term “in plan view” as used herein refers to viewing the nitride semiconductor device 10 from above along the Z-axis direction unless explicitly stated otherwise.

The buffer layer 14 may be located between the semiconductor substrate 12 and the electron transit layer 16. The buffer layer 14 may be made of any material that mitigates lattice mismatch between the semiconductor substrate 12 and the electron transit layer 16. In one example, the buffer layer 14 may be made of any material that facilitates epitaxial growth of the electron transit layer 16.

The buffer layer 14 may include one or more nitride semiconductor layers. In one example, the buffer layer 14 may include at least one of an aluminum nitride (AlN) layer, an aluminum gallium nitride (AlGaN) layer, and a graded AlGaN layer having different aluminum (Al) compositions. For example, the buffer layer 14 may be formed by a single AlN layer, a single AlGaN layer, a layer having an AlGaN/GaN superlattice structure, a layer having an AlN/AlGaN superlattice structure, a layer having an AlN/GaN superlattice structure, or a combination of two or more of the above-described five layers.

In one example, the buffer layer 14 may include a first buffer layer formed on the semiconductor substrate 12 and a second buffer layer formed on the first buffer layer. The first buffer layer may be, for example, an AlN layer having a thickness of 200 nm. The second buffer layer may be, for example, multiple AlGaN layers each having a thickness of 100 nm.

In order to suppress a leakage current in the buffer layer 14, an impurity may be introduced into a part of the buffer layer 14 to make the buffer layer 14 semi-insulating. In this case, the impurity is, for example, carbon (C) or iron (Fe), and the concentration of the impurity may be, for example, 4×10¹⁶ cm⁻³ or more.

The electron transit layer 16 is made of a nitride semiconductor. The electron transit layer 16 is, for example, a GaN layer. The thickness of the electron transit layer 16 is, for example, in a range of 0.1 m to 2 m. In order to suppress the leakage current in the electron transit layer 16, an impurity may be introduced into a part of the electron transit layer 16 to make the region other than a surface layer region of the electron transit layer 16 semi-insulating. In this case, the impurity is, for example, C, and the peak concentration of the impurity in the electron transit layer 16 is, for example, 1×10¹⁹ cm⁻³ or more.

The electron supply layer 18 is made of a nitride semiconductor having a band gap larger than a band gap of the electron transit layer 16. The electron supply layer 18 is, for example, an AlGaN layer. In this case, since the band gap increases as an Al composition increases, the electron supply layer 18, which is the AlGaN layer, has a larger band gap than a band gap of the electron transit layer 16, which is the GaN layer. In one example, the electron supply layer 18 is made of AlₓGa₁₋ₓN, where x is 0.1<x<0.4, and more preferably 0.2<x<0.3. However, the example is not necessarily limited to this range. The thickness of the electron supply layer 18 is, for example, in a range of 5 nm to 20 nm.

The electron transit layer 16 and the electron supply layer 18 are made of nitride semiconductors having lattice constants different from each other. Therefore, the nitride semiconductor (for example, GaN) forming the electron transit layer 16 and the nitride semiconductor (for example, AlGaN) forming the electron supply layer 18 form a lattice mismatch system heterojunction. By spontaneous polarization of the electron transit layer 16 and the electron supply layer 18 and piezoelectric polarization caused by a stress applied to the electron supply layer 18 near the heterojunction interface, an energy level of the conduction band of the electron transit layer 16 near the heterojunction interface becomes lower than the Fermi level. As a result, a two-dimensional electron gas (2DEG) spreads in the electron transit layer 16 at a position (for example, within a range of about several nm from the interface) near the heterojunction interface between the electron transit layer 16 and the electron supply layer 18.

As illustrated in FIGS. 1 to 3, each of the electron transit layer 16 and the electron supply layer 18 includes an active region 21 where the 2DEG is generated and an inactive region 22 disposed around the active region 21 and where the 2DEG is less likely to be generated.

As illustrated in FIG. 1, the active region 21 is formed in, for example, a rectangular shape in plan view. Specifically, the active region 21 has a rectangular shape with the X-axis direction as one side and the Y-axis direction as the other side. However, the planar shape of the active region 21 is not limited thereto, and may be a trapezoidal shape, an oval shape, a circular shape, or any other shape.

An impurity for making the 2DEG less likely to be generated is introduced into the inactive region 22. The impurity is an impurity different from an acceptor impurity contained in the gate layer 30 described later. The impurity may be, for example, a relatively light element. Examples of the impurity include helium (He), boron (B), nitrogen (N), oxygen (O), fluorine (F), and argon (Ar). The impurity for making the 2DEG less likely to be generated is also an impurity that inhibits the generation of the 2DEG.

A resistance value of the inactive region 22 is higher than a resistance value of the active region 21. In the present embodiment, by introducing the impurity into the inactive region 22, the resistance value of the inactive region 22 is higher than the resistance value of the active region 21. In other words, the inactive region 22 is a region having a higher resistance value than that of the active region 21.

The inactive region 22 is formed so as to surround the active region 21. That is, the inactive region 22 is disposed on both sides of the active region 21 in the X-axis direction, and is disposed on both sides of the active region 21 in the Y-axis direction.

The gate layer 30 is made of a nitride semiconductor having a band gap smaller than a band gap of the electron supply layer 18. For example, when the electron supply layer 18 is the AlGaN layer, the gate layer 30 may be a GaN layer containing the acceptor impurity. The acceptor impurity may contain at least one of zinc (Zn), magnesium (Mg), and carbon (C). The maximum concentration of the acceptor impurity in the gate layer 30 is, for example, in a range of 7×1018 cm⁻³ to 1×10²⁰ cm⁻³.

In the present embodiment, the acceptor impurity contained in the gate layer 30 is different from the impurity introduced into the inactive region 22, specifically, the impurity for making the 2DEG less likely to be generated.

As described above, when the gate layer 30 contains the acceptor impurity, energy levels of the electron transit layer 16 and the electron supply layer 18 are raised. Therefore, in the region immediately below the gate layer 30, the energy level of the conduction band of the electron transit layer 16 near the heterojunction interface between the electron transit layer 16 and the electron supply layer 18 is substantially the same as or higher than the Fermi level. Therefore, at the time of zero bias when no voltage is applied to the gate (specifically, a first gate electrode 51), the 2DEG is not formed in the electron transit layer 16 in the region immediately below the gate layer 30. On the other hand, the 2DEG is formed in the electron transit layer 16 in the active region 21 other than the region immediately below the gate layer 30.

As described above, the 2DEG disappears in the region immediately below the gate layer 30 due to the presence of the gate layer 30 doped with the acceptor impurity. As a result, the normally-off operation of the transistor is realized.

The thickness of the gate layer 30 is not particularly limited, and can be appropriately determined in consideration of a gate breakdown voltage and the like. For example, the thickness of the gate layer 30 may be in a range of 50 nm to 150 nm. Furthermore, a cross-sectional shape of the gate layer 30 along a ZX plane in FIG. 2 is not particularly limited, and may be, for example, a rectangular shape, a trapezoidal shape, a ridge shape, or any other shape.

As illustrated in FIG. 1, in the present embodiment, the gate layer 30 is disposed so as to extend over both the active region 21 and the inactive region 22. Specifically, the gate layer 30 extends in the Y-axis direction so as to traverse the active region 21. The gate layer 30 includes a wide portion having a relatively wide width in the X-axis direction and a narrow portion having a width narrower than a width of the wide portion. The wide portion is located at an end portion of the gate layer 30 in the Y axis direction. The wide portion is provided on the inactive region 22. The narrow portion extends in the Y axis direction from the wide portion, and is disposed on the active region 21 and both sides of the active region 21 in the Y direction. In this case, the active region 21 is divided into two regions by the gate layer 30.

The gate layer 30 includes a first parts 31 formed on the active region 21 and a second parts 32 formed on the inactive region 22.

As described above, the first parts 31 extend in the Y-axis direction so as to traverse the active region 21. In the present embodiment, while the acceptor impurity is introduced into the first parts 31, the impurity for making the 2DEG less likely to be generated is not introduced into the first parts 31.

The second parts 32 are provided on both sides of the first parts 31 in the Y axis direction. Both the acceptor impurity and the impurity for making the 2DEG less likely to be generated are introduced into the second parts 32 of the present embodiment.

The nitride semiconductor device 10 includes a source electrode 41 and a drain electrode 42, which are in contact with an upper surface 18a of the electron supply layer 18.

The source electrode 41 and the drain electrode 42 are made of the same material. For example, the source electrode 41 and the drain electrode 42 may include one or more metal layers. As one example, the source electrode 41 and the drain electrode 42 may include one or a combination of two or more metal layers selected from a group including a titanium (Ti) layer, a palladium (Pd) layer, a nickel (Ni) layer, a titanium nitride (TiN) layer, an aluminum (Al) layer, an aluminum silicon copper (AlSiCu) layer, an aluminum copper (AlCu) layer, and the like.

The source electrode 41 and the drain electrode 42 may be in ohmic contact with the electron supply layer 18. In other words, the source electrode 41 and the drain electrode 42 may be made of a material that is in ohmic contact with the electron supply layer 18.

The source electrode 41 and the drain electrode 42 are disposed so as to sandwich the gate layer 30. Specifically, the source electrode 41 and the drain electrode 42 are disposed on the opposite sides of the first parts 31 in the X axis direction in the active region 21. Therefore, in the active region 21, the gate layer 30 is interposed between the source electrode 41 and the drain electrode 42. In other words, the source electrode 41 and the drain electrode 42 are disposed in two regions, respectively, divided by the gate layer 30.

A distance between the drain electrode 42 and the gate layer 30 in the X-axis direction may be set longer than a distance between the source electrode 41 and the gate layer 30 in the X-axis direction. However, both distances are arbitrary, and may be, for example, the same.

### First Gate Electrode and Second Gate Electrode

As illustrated in FIGS. 1 to 3, the nitride semiconductor device 10 includes the first gate electrode 51 and a second gate electrode 52, which are in contact with an upper surface 30a of the gate layer 30.

The first gate electrode 51 is configured to form a Schottky junction with the gate layer 30, for example. Specifically, the first gate electrode 51 is made of a material that readily forms the Schottky junction with the gate layer 30. For example, the first gate electrode 51 may be made of titanium nitride (TiN), tantalum nitride (TaN), tungsten nitride (WN), titanium silicon nitride (TiSiN), tantalum silicon nitride (TaSiN), tungsten silicide (WSi), tungsten silicon nitride (WSiN), or the like.

At least a part of the first gate electrode 51 is formed on the first parts 31. In the present embodiment, the first gate electrode 51 is formed on substantially the entire region of the gate layer 30. The first gate electrode 51 is formed to extend over both the first parts 31 on the active region 21 and the second parts 32 on the inactive region 22. Therefore, the first gate electrode 51 is formed to extend over both the active region 21 and the inactive region 22. The first gate electrode 51 extends in the Y-axis direction to traverse the active region 21 so as to be interposed between the source electrode 41 and the drain electrode 42 in the active region 21.

According to such a configuration, when an appropriate on-voltage is applied to the first gate electrode 51, a channel by the 2DEG is formed in the electron transit layer 16 in the region immediately below the first gate electrode 51. As a result, conduction is established between the source and the drain.

The second gate electrode 52 is made of a material different from the material of the first gate electrode 51. For example, the second gate electrode 52 is made of a material having a work function higher than that of the first gate electrode 51. That is, the second gate electrode 52 may be configured such that a Schottky barrier between the second gate electrode 52 and the gate layer 30 is smaller than a Schottky barrier between the first gate electrode 51 and the gate layer 30. Alternatively, the second gate electrode 52 may be made of a material that is readily in ohmic contact with the gate layer 30. As one example, the second gate electrode 52 may contain any of Ti, Pd, and Ni.

In the present embodiment, the second gate electrode 52 is made of the same material as the source electrode 41 and the drain electrode 42. For example, the second gate electrode 52, the source electrode 41, and the drain electrode 42 may be made of Ti/Al. However, the present disclosure is not limited thereto, and the second gate electrode 52, the source electrode 41, and the drain electrode 42 may be made of different materials.

As illustrated in FIG. 3, the second gate electrode 52 is in contact with the gate layer 30. Specifically, an opening 60 for exposing the gate layer 30 is formed in the first gate electrode 51. In the present embodiment, the opening 60 is formed in a portion of the first gate electrode 51 on the inactive region 22. The opening 60 exposes, a part of the gate layer 30, specifically the second parts 32. The second gate electrode 52 is in contact with the gate layer 30 via the opening 60. As a result, the second gate electrode 52 and the gate layer 30 are electrically connected to each other.

In the present embodiment, the second gate electrode 52 is formed on one of the second parts 32. Specifically, the second gate electrode 52 is disposed on the inactive region 22 and is in contact with the second part 32.

The second gate electrode 52 includes an embedded portion 52a embedded in the opening 60 and an overlap portion 52b.

The embedded portion 52a is in contact with the gate layer 30 (the second part 32 in the present embodiment). The embedded portion 52a is surrounded by the first gate electrode 51 in plan view. The embedded portion 52a is in contact with a side surface 60a of the opening 60. For example, the embedded portion 52a is in contact with the first gate electrode 51 over the entire circumference in plan view. In the present embodiment, shapes of the opening 60 and the embedded portion 52a in plan view are square. However, the example is not limited thereto, and the planar shapes of the opening 60 and the embedded portion 52a are arbitrary, and may be, for example, a rectangular shape having long sides and short sides or may be a circular shape.

The overlap portion 52b is formed to be slightly larger than the embedded portion 52a in plan view, and protrudes laterally from the opening 60. The overlap portion 52b is in contact with an upper surface 51a of the first gate electrode 51, specifically, a peripheral portion of the opening 60 in the first gate electrode 51. As a result, a contact area between the first gate electrode 51 and the second gate electrode 52 is increased.

A contact area between the first gate electrode 51 and the gate layer 30 is referred to as a first contact area S1, and a contact area between the second gate electrode 52 and the gate layer 30 is referred to as a second contact area S2. The second contact area S2 is smaller than the first contact area S1. For example, the second contact area S2 may be 1/100 or less of the first contact area S1.

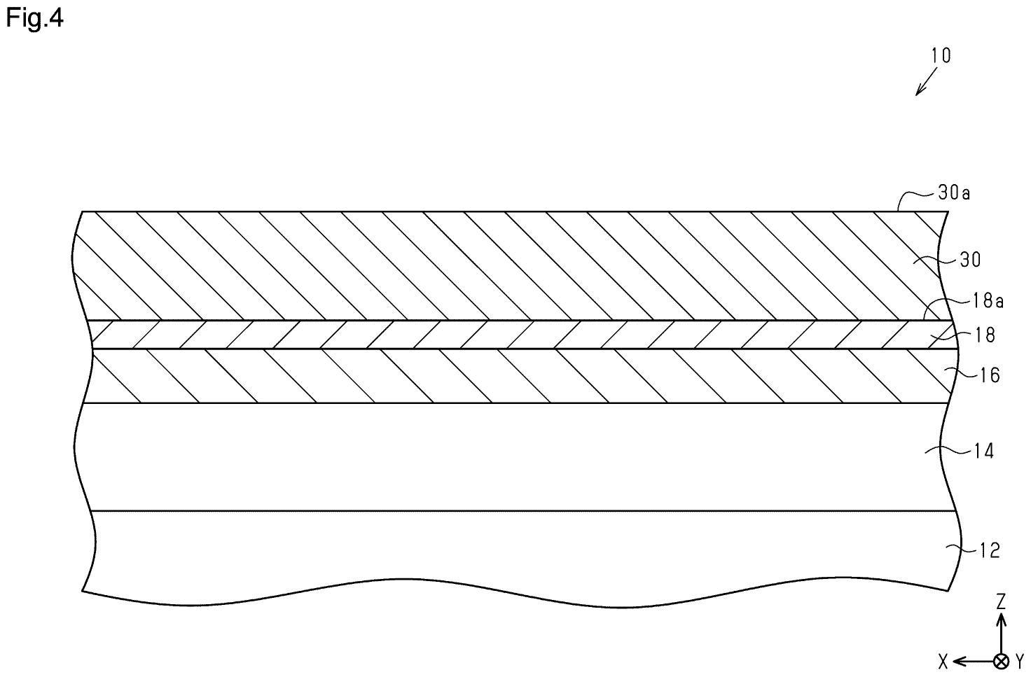

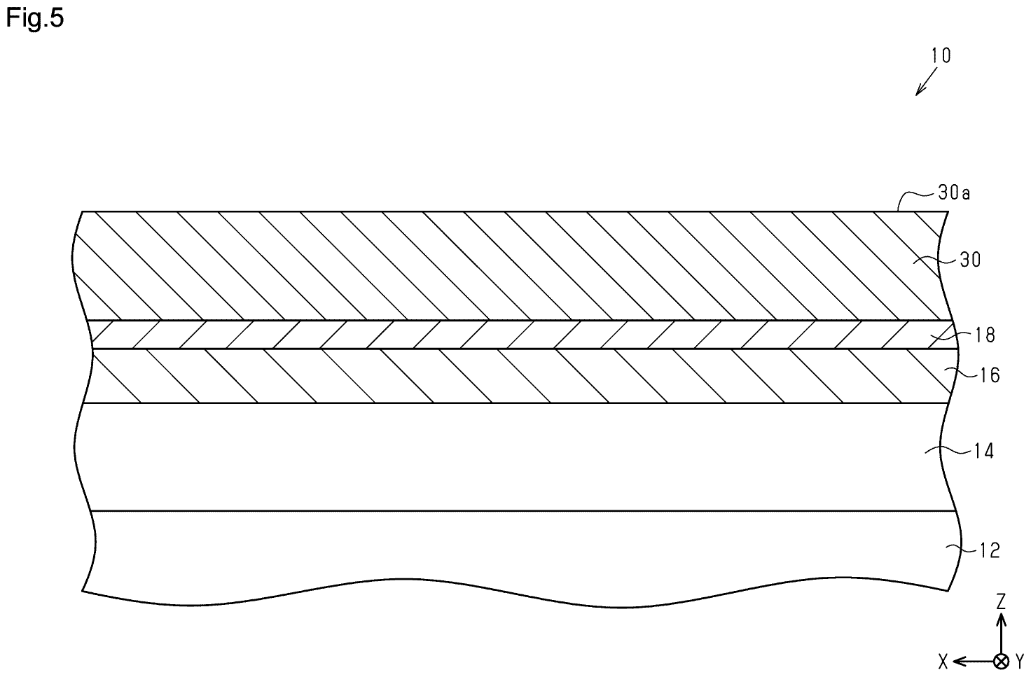

Next, a method for manufacturing the nitride semiconductor device 10 according to the present embodiment will be described with reference to FIGS. 4 to 13. Each of FIGS. 4, 6, 8, 10, and 12 is a schematic cross-sectional view taken along line 2-2 of a respective one of steps, and each of FIGS. 5, 7, 9, 11, and 13 is a schematic cross-sectional view taken along line 3-3 of a respective one of the steps.

As illustrated in FIGS. 4 and 5, the method for manufacturing the nitride semiconductor device 10 includes a step of forming the buffer layer 14, the electron transit layer 16, the electron supply layer 18, and the gate layer 30 on the semiconductor substrate 12. This step uses epitaxial growth by metal organic chemical vapor deposition (MOCVD), for example. In this step, the gate layer 30 is formed on the entire upper surface 18a of the electron supply layer 18 regardless of the active region 21 and the inactive region 22.

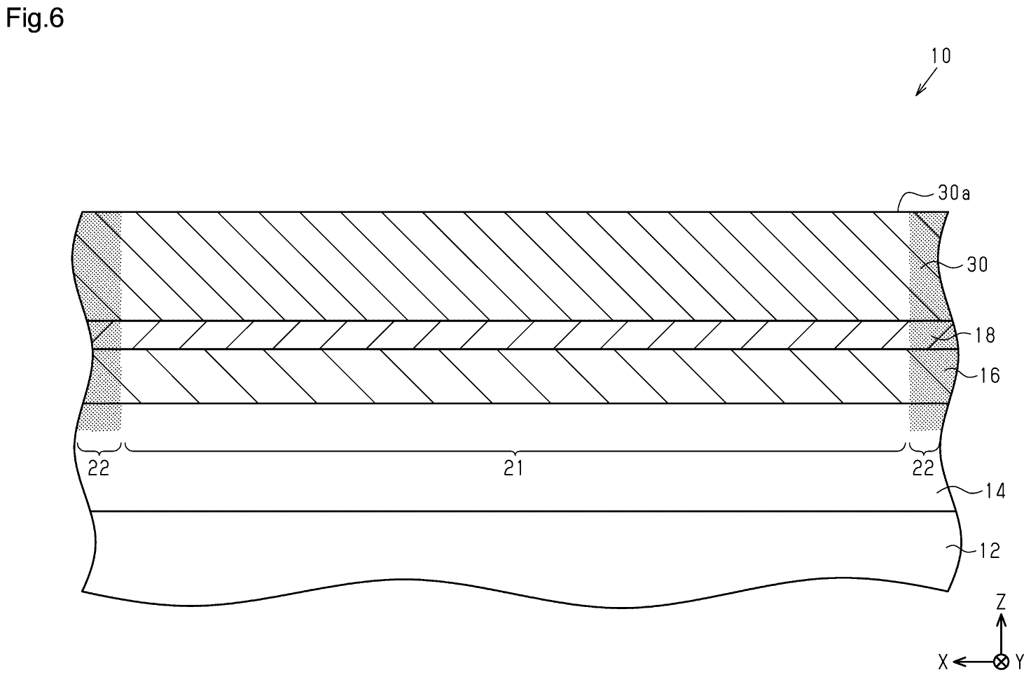

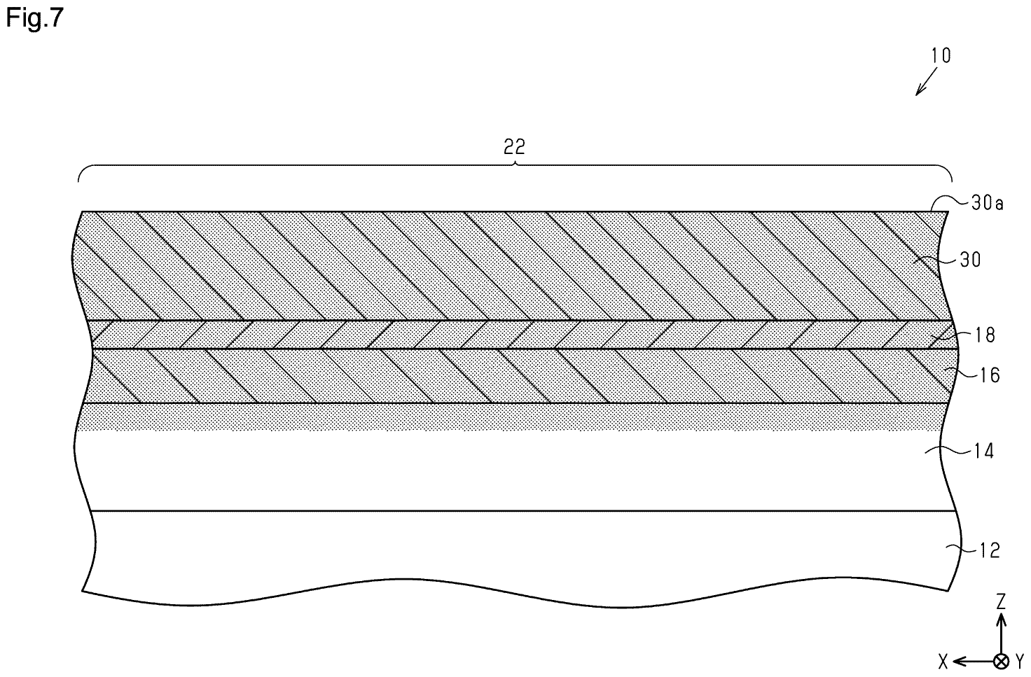

As illustrated in FIGS. 6 and 7, next, the method for manufacturing the nitride semiconductor device 10 includes a step of forming the inactive region 22. Specifically, the step includes, for example, a step of forming a resist as a mask only in the active region 21, and a step of ion-implanting an impurity for making the 2DEG less likely to be generated into both the active region 21 and the inactive region 22. As a result, the above-described impurity is introduced into the inactive region 22 where no resist is formed.

Specifically, the impurity is introduced into the gate layer 30 in the inactive region 22. As a result, the second parts 32 are formed. The impurity is introduced into the electron supply layer 18 and the electron transit layer 16 through the gate layer 30. The impurity may be implanted or need not be implanted into a part of the buffer layer 14. On the other hand, the impurity is not introduced into the gate layer 30, the electron supply layer 18, and the electron transit layer 16 in the active region 21 where the resist is formed.

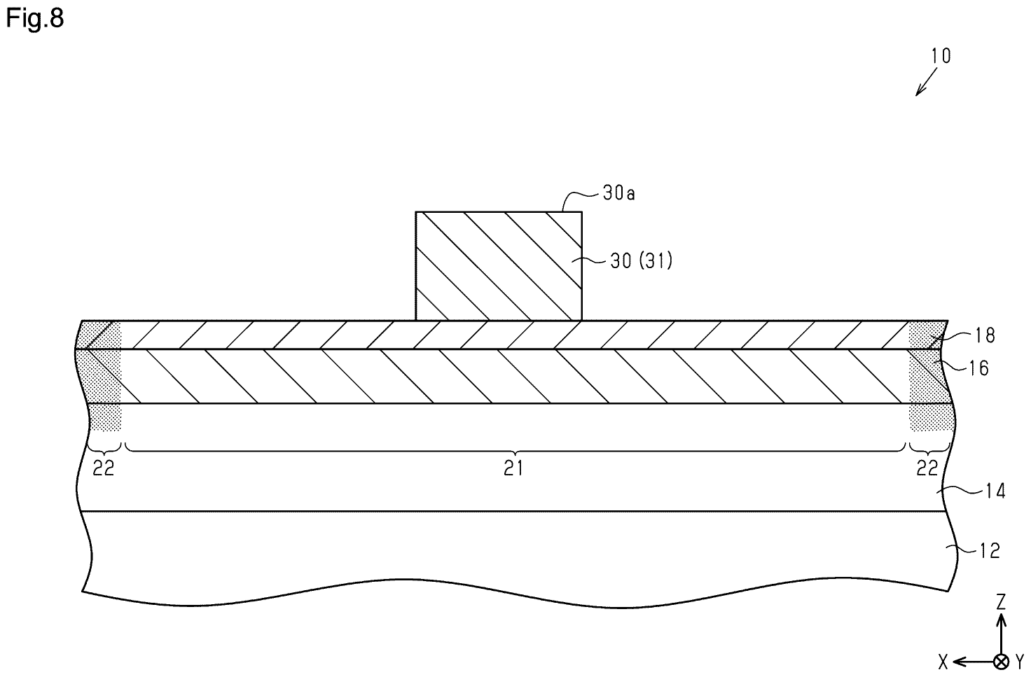

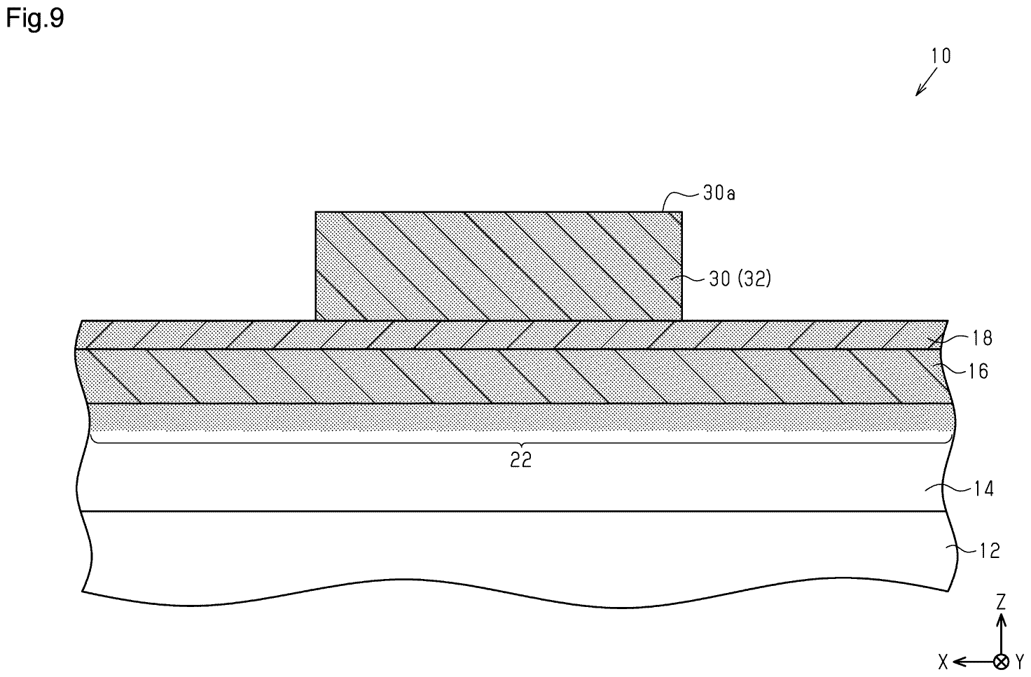

As illustrated in FIGS. 8 and 9, the method for manufacturing the nitride semiconductor device 10 includes a step of etching the gate layer 30. As a result, the gate layer 30 having a shape as illustrated in FIG. 1 is formed.

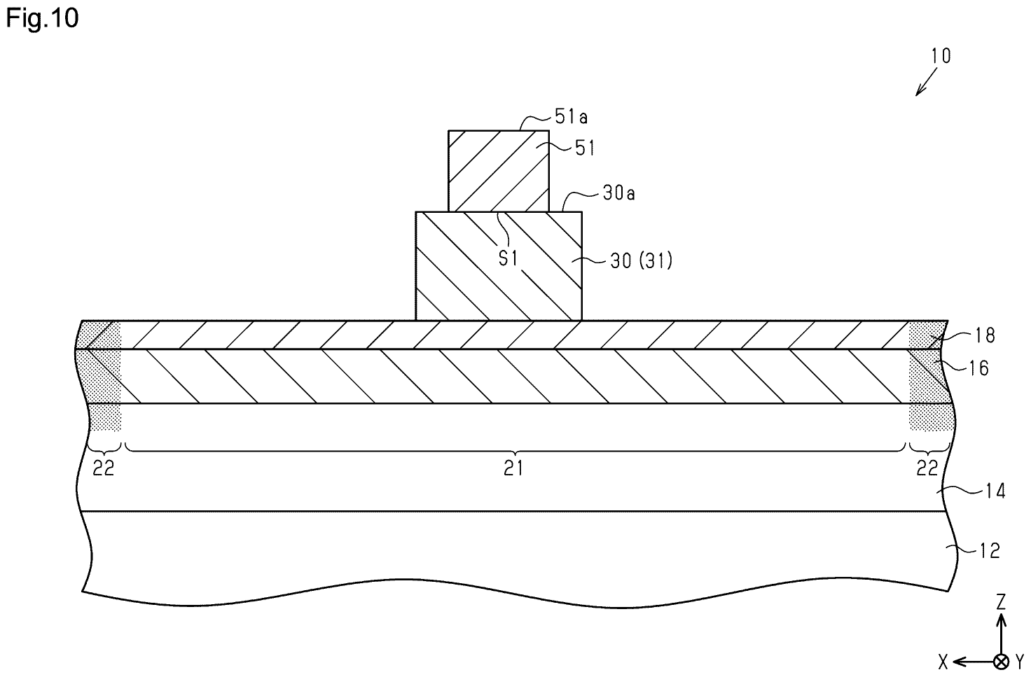

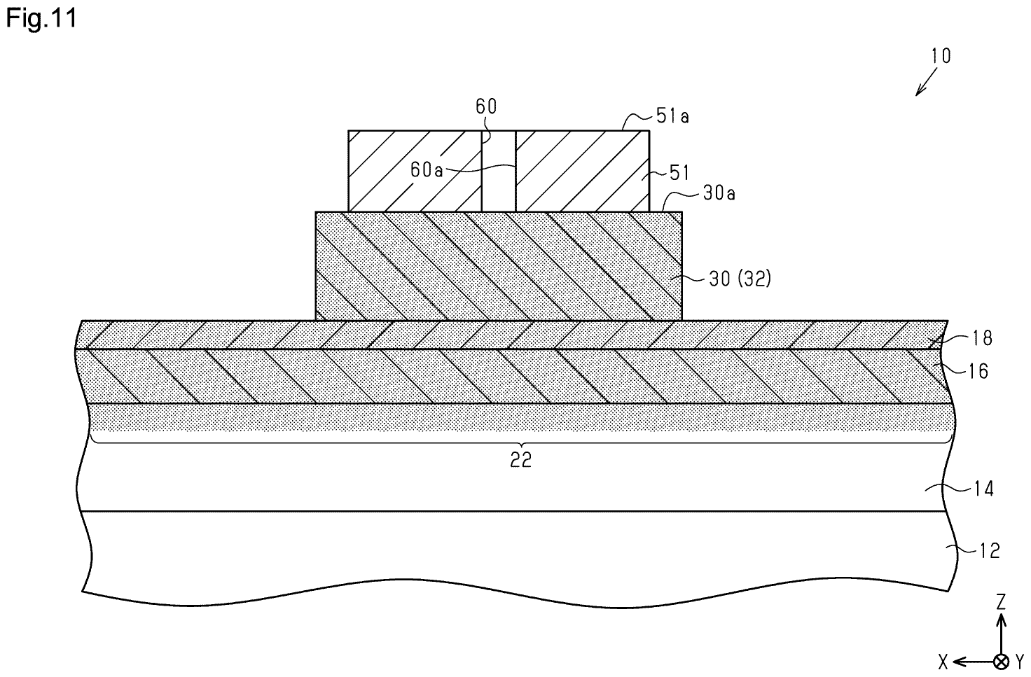

As illustrated in FIGS. 10 and 11, the method for manufacturing the nitride semiconductor device 10 includes a step of forming the first gate electrode 51 on the gate layer 30. The step may be a step of etching only a necessary portion using a resist after the first gate electrode 51 is formed on the entire surface by using sputtering or the like, for example. In this case, a resist is preferably not provided at a portion corresponding to the opening 60 so that the opening 60 is formed at the time of etching.

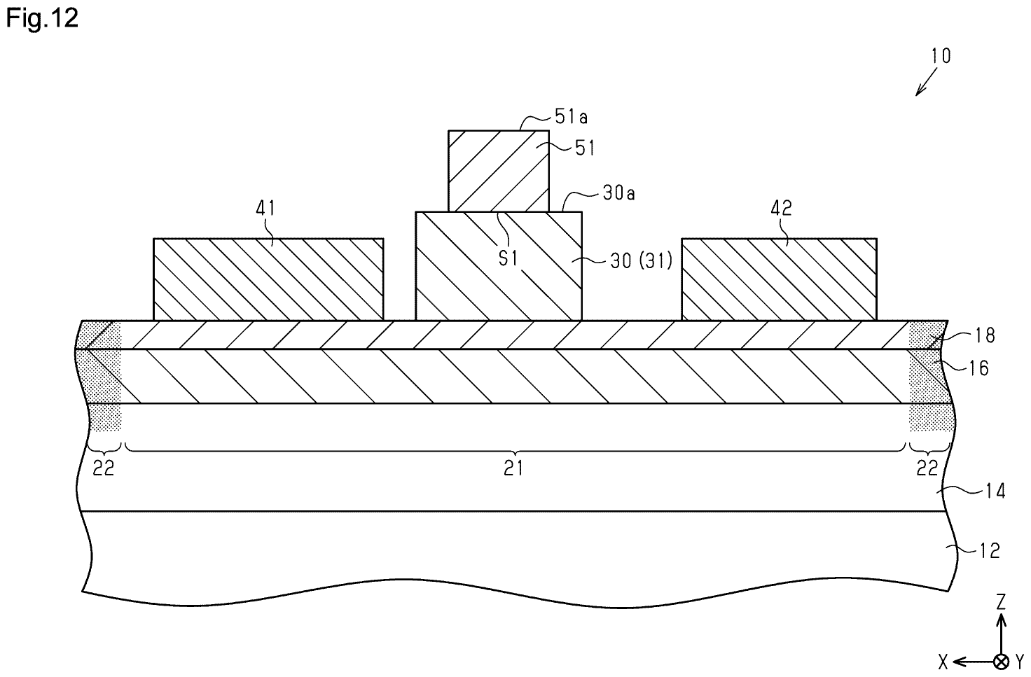

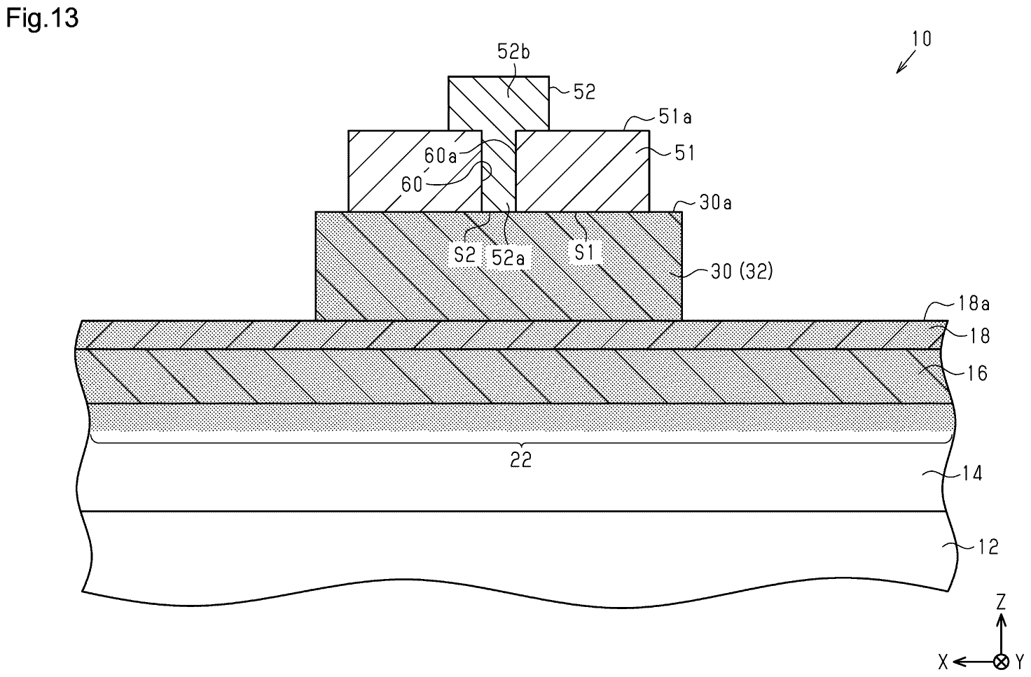

As illustrated in FIGS. 12 and 13, the method for manufacturing the nitride semiconductor device 10 includes a step of forming the source electrode 41, the drain electrode 42, and the second gate electrode 52. In the present embodiment, the source electrode 41, the drain electrode 42, and the second gate electrode 52 may be formed simultaneously. Specifically, the second gate electrode 52 may be formed on the entire surface, and then etching may be performed using a resist while leaving only the portions corresponding to the source electrode 41, the drain electrode 42, and the second gate electrode 52. In this case, the source electrode 41, the drain electrode 42, and the second gate electrode 52 are made of the same material (for example, Ti/Al).

However, the example is not limited thereto, and the step of forming the source electrode 41 and the drain electrode 42 and the step of forming the second gate electrode 52 may be separate steps. In this case, the second gate electrode 52 can be made of a material (for example, Ni or Pd) different from a material of the source electrode 41 and the drain electrode 42.

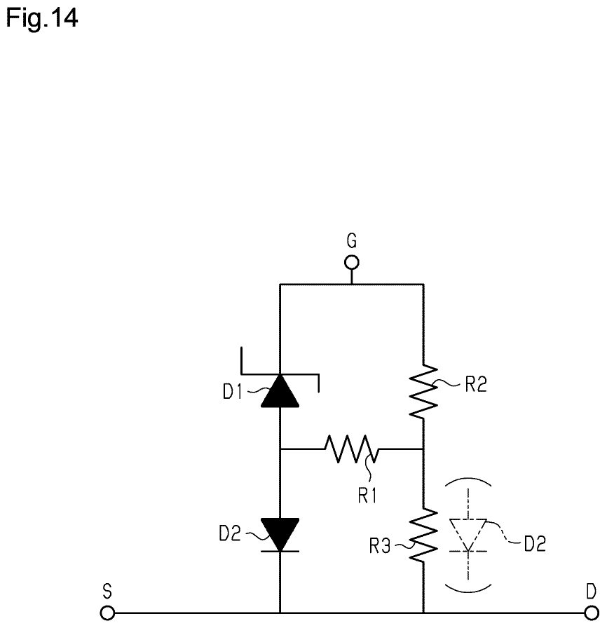

Next, operation of the present embodiment will be described with reference to FIG. 14. FIG. 14 is a schematic equivalent circuit diagram around the gate layer 30 in the nitride semiconductor device 10 according to the present embodiment.

As illustrated in FIG. 14, the nitride semiconductor device 10 includes a gate layer resistance R1 that is a resistance component of the gate layer 30, a Schottky barrier diode D1, and a pin diode D2.

The Schottky barrier diode D1 is formed by the gate layer 30 and the first gate electrode 51. A gate voltage is applied to the gate layer resistance R1 via the Schottky barrier diode D1. The pin diode D2 is formed by the 2DEG of the gate layer 30/the electron supply layer 18/the electron transit layer 16. The pin diode D2 is provided between the gate layer resistance R1 and the source electrode 41 and the gate layer resistance R1 and the drain electrode 42.

That is, the gate layer 30 is electrically sandwiched between the Schottky barrier diode D1 and the pin diode D2. In this case, when a voltage is applied between the gate and the source or between the gate and the drain, holes are released or accumulated in the gate layer 30. Thereafter, even when the applied voltage is removed, the gate layer 30 is sandwiched between the barriers of the Schottky barrier diode D1 and the pin diode D2, so that a potential of the gate layer 30 becomes unstable as a floating state. As a result, it takes time for the released or accumulated holes to recover to their original state, so that a threshold voltage will fluctuate over time. When the threshold voltage fluctuates in a negative direction, it is likely to be erroneously turned on due to a noise. On the other hand, when the threshold voltage fluctuates in a positive direction, the on-resistance increases and a power loss may increase.

In this regard, in the present embodiment, the second gate electrode 52 is provided separately from the first gate electrode 51. The second gate electrode 52 is made of a material having a work function higher than that of the first gate electrode 51. As one example, the second gate electrode 52 is configured to be in ohmic contact with the gate layer 30. As a result, the nitride semiconductor device 10 includes a second gate resistance R2 provided between the gate layer resistance R1 and the gate separately from the Schottky barrier diode D1. As a result, inflow and outflow of holes from the second gate electrode 52 to the gate layer 30 readily occur. Therefore, since the potential of the gate layer 30 is stabilized, the threshold voltage is less likely to fluctuate.

For example, when a negative voltage is applied to the first gate electrode 51, the voltage is applied to the Schottky barrier diode D1 in the forward direction, so that holes in the gate layer 30 are released from the gate layer 30. On the other hand, since holes enter the gate layer 30 via the second gate electrode 52, the released holes are immediately recovered. Therefore, the fluctuation of the threshold voltage caused by the gate layer 30 is suppressed.

In the present embodiment, the Schottky barrier between the second gate electrode 52 and the gate layer 30 is smaller than the Schottky barrier between the first gate electrode 51 and the gate layer 30. In this case, there is a concern that a gate leakage current via the second gate electrode 52 increases.

In this regard, in the present embodiment, since the second contact area S2 is smaller than the first contact area S1, the second gate resistance R2 is likely to be increased. Therefore, the gate leakage current via the second gate electrode 52 is reduced.

In the present embodiment, the second gate electrode 52 is formed on the inactive region 22. Specifically, the second gate electrode 52 is formed on the second part 32 on the inactive region 22. As a result, a region immediately below the second gate electrode 52 is a high resistance region. Therefore, the second gate electrode 52 is electrically connected to the source and the drain via an inactive region resistance R3 instead of the pin diode D2.

This inactive region resistance R3 reduces a current flowing from the second gate electrode 52 to the source or the drain. As a result, the gate leakage current caused by the second gate electrode 52 is reduced.

According to the present embodiment described in detail above, the following advantages are exhibited.

(1-1) The nitride semiconductor device 10 includes the electron transit layer 16, the electron supply layer 18, the gate layer 30, the first gate electrode 51, the source electrode 41, and the drain electrode 42. The electron transit layer 16 is made of the nitride semiconductor. The electron supply layer 18 is formed on the electron transit layer 16 and is made of the nitride semiconductor having the band gap larger than the band gap of the electron transit layer 16. The gate layer 30 is formed on the electron supply layer 18 and is made of the nitride semiconductor containing the acceptor impurity. The first gate electrode 51 is in contact with the upper surface 30a of the gate layer 30. The source electrode 41 and the drain electrode 42 are disposed so as to sandwich the gate layer 30, and are in contact with the upper surface 18a of the electron supply layer 18.

In such a configuration, the nitride semiconductor device 10 includes the second gate electrode 52 made of the material different from the material of the first gate electrode 51. The second gate electrode 52 is in contact with the upper surface 30a of the gate layer 30. The second contact area S2, which is the contact area between the second gate electrode 52 and the gate layer 30, is smaller than the first contact area S1, which is the contact area between the first gate electrode 51 and the gate layer 30.

According to such a configuration, holes can be accumulated or released in the gate layer 30 via the second gate electrode 52, so that the potential of the gate layer 30 is stabilized. As a result, the fluctuation of the threshold voltage caused by the gate layer 30 is suppressed. In addition, since the second contact area S2 is smaller than the first contact area S1, the gate leakage current via the second gate electrode 52 is suppressed. Therefore, the fluctuation of the threshold voltage caused by the gate layer 30 is suppressed while suppressing an increase in the gate leakage current.

(1-2) The second gate electrode 52 may be made of a material having a work function higher than that of the first gate electrode 51. For example, the second gate electrode 52 may contain any of Ti, Pd, and Ni.

According to such a configuration, the Schottky barrier between the second gate electrode 52 and the gate layer 30 is likely to be smaller than the Schottky barrier between the first gate electrode 51 and the gate layer 30. As a result, exchange of holes via the second gate electrode 52 is readily performed. Therefore, the advantage of (1-1) is exhibited.

(1-3) The second gate electrode 52 may be configured to be in ohmic junction with the gate layer 30.

Such a configuration allows exchange of holes between the second gate electrode 52 and the gate layer 30 to be performed smoothly. As a result, the advantage of (1-1) is more suitably exhibited.

(1-4) The second gate electrode 52 may be made of the same material as the source electrode 41 and the drain electrode 42.

Such a configuration allows the second gate electrode 52 to be formed simultaneously with the source electrode 41 and the drain electrode 42. As a result, an increase in the manufacturing process caused by providing the second gate electrode 52 is suppressed.

(1-5) The second contact area S2 may be 1/100 or less of the first contact area S1. As a result, the gate leakage current is more suitably suppressed.

(1-6) The first gate electrode 51 is configured to form the Schottky junction with the gate layer 30.

According to such a configuration, the Schottky barrier diode D1 is formed by the first gate electrode 51 and the gate layer 30. When a voltage in the positive direction is applied to the first gate electrode 51, a reverse bias is applied to the Schottky barrier diode D1, and the gate layer 30 is depleted. As a result, the gate layer 30 operates like an insulated gate, so that the gate leakage current is reduced. Therefore, for example, a gate drive circuit similar to the MOSFET may be used as a circuit for driving the nitride semiconductor device 10.

On the other hand, when the Schottky barrier diode D1 is formed, as described above, unintended accumulation or release of holes is likely to be performed, so that the potential may be unstable.

In this regard, in the present embodiment, since the second gate electrode 52 is provided separately from the first gate electrode 51 as described above, even when the first gate electrode 51 forms the Schottky junction with the gate layer 30 as described above, the fluctuation of the threshold voltage caused by the gate layer 30 is suppressed.

(1-7) The first gate electrode 51 contains any of TiN, TaN, WN, TiSiN, TaSiN, WSi, and WSiN.

According to such a configuration, by adopting the above material as the first gate electrode 51, the first gate electrode 51 and the gate layer 30 readily form the Schottky junction.

In addition, TiN, TaN, WN, TiSiN, TaSiN, WSi, and WSiN are materials that are readily micromachined by etching. Therefore, the first gate electrode 51 and the opening 60 is formed with high precision.

(1-8) The electron transit layer 16 and the electron supply layer 18 include the active region 21 where the 2DEG is generated and the inactive region 22 where the 2DEG is less likely to be generated than in the active region 21. The gate layer 30 includes the first parts 31 formed on the active region 21 and the second parts 32 formed on the inactive region 22. At least a part of the first gate electrode 51 is formed on the first parts 31. The second gate electrode 52 is formed on one of the second parts 32.

According to such a configuration, the inactive region 22 is present immediately below the second gate electrode 52. The inactive region 22 is a region having a higher resistance value than that of the active region 21. As a result, a gate current flowing directly from the second gate electrode 52 to the source electrode 41 or the drain electrode 42 without passing through the gate layer 30. Therefore, the gate leakage current caused by providing the second gate electrode 52 is suppressed.

(1-9) The inactive region 22 contains the impurity for making the 2DEG less likely to be generated. According to such a configuration, the inactive region 22 can be achieved by ion-implanting the impurity. Such a method of an increase in resistance by introducing the impurity allows the flatness of the electron supply layer 18 and the like to be readily maintained as compared with a method of an increase in resistance by removing the 2DEG generation region by mesa etching. Therefore, it is suitable for integration.

(1-10) Examples of the impurity for making the 2DEG less likely to be generated include any of He, B, N, O, F, and Ar. According to this configuration, a relatively light element is employed as the impurity for making the 2DEG less likely to be generated. As a result, since the ion implantation from above reaches the depth of the 2DEG, it is possible to form the inactive region 22 by increasing the resistance of the 2DEG.

In particular, when O, F, and Ar are used as the impurity for making the 2DEG less likely to be generated, divalent ions may be adopted as 0, F, and Ar. As a result, an acceleration voltage of the ion implantation can be substantially doubled, and the impurity can be introduced into a deep region.

(1-11) The opening 60 for exposing the gate layer 30 is formed in the first gate electrode 51. The second gate electrode 52 includes the embedded portion 52a embedded in the opening 60. The embedded portion 52a is in contact with the gate layer 30.

According to such a configuration, the embedded portion 52a is surrounded by the first gate electrode 51. As a result, the depletion layer from the first gate electrode 51 extends in the planar direction and readily spreads to the region immediately below the embedded portion 52a. Therefore, the gate current from the second gate electrode 52 is reduced. Therefore, the gate leakage current is suppressed.

(1-12) The embedded portion 52a is in contact with the side surface 60a of the opening 60 in the first gate electrode 51. The second gate electrode 52 includes the overlap portion 52b formed to be wider than the opening 60 in plan view. The overlap portion 52b is in contact with the upper surface 51a of the first gate electrode 51.

According to such a configuration, the contact area between the first gate electrode 51 and the second gate electrode 52 is increased by the overlap portion 52b. As a result, a contact resistance between the first gate electrode 51 and the second gate electrode 52 is reduced without separately providing a wiring line that electrically connects the first gate electrode 51 and the second gate electrode 52 to each other.

In particular, when the opening 60 is increased in order to increase the contact area between the gate electrodes 51 and 52, there is a concern that the second contact area S2 may increase and the gate leakage current may increase. In this regard, according to the present embodiment, by providing the overlap portion 52b, the contact area between the gate electrodes 51 and 52 can be increased without increasing the size of the opening 60. Therefore, the contact area between the gate electrodes 51 and 52 can be increased while suppressing the increase in the gate leakage current.

### Modifications of First Embodiment

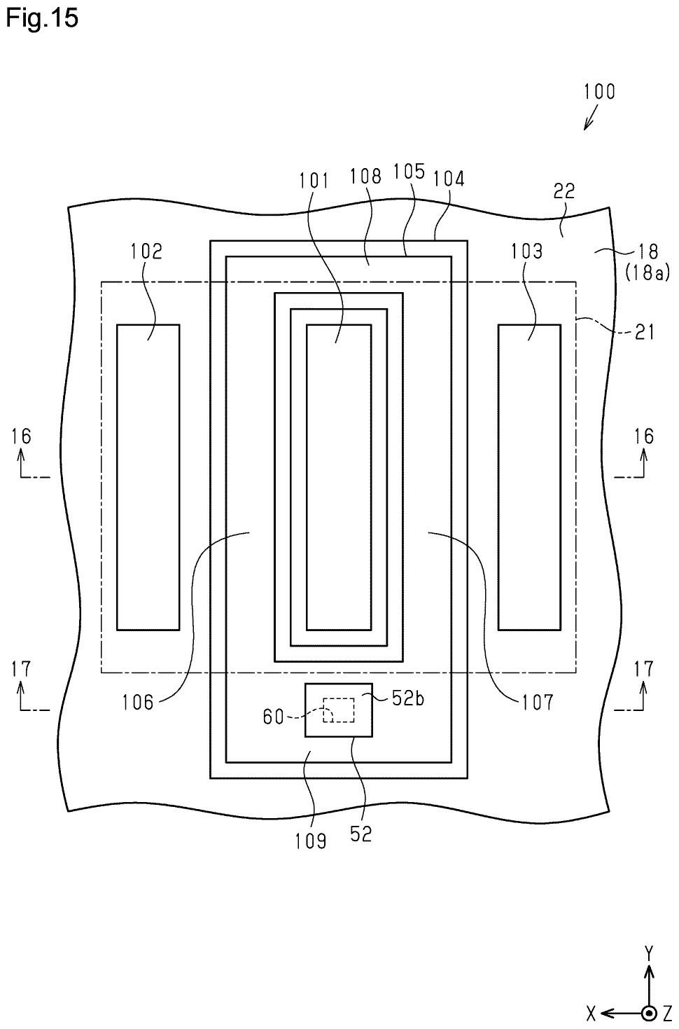

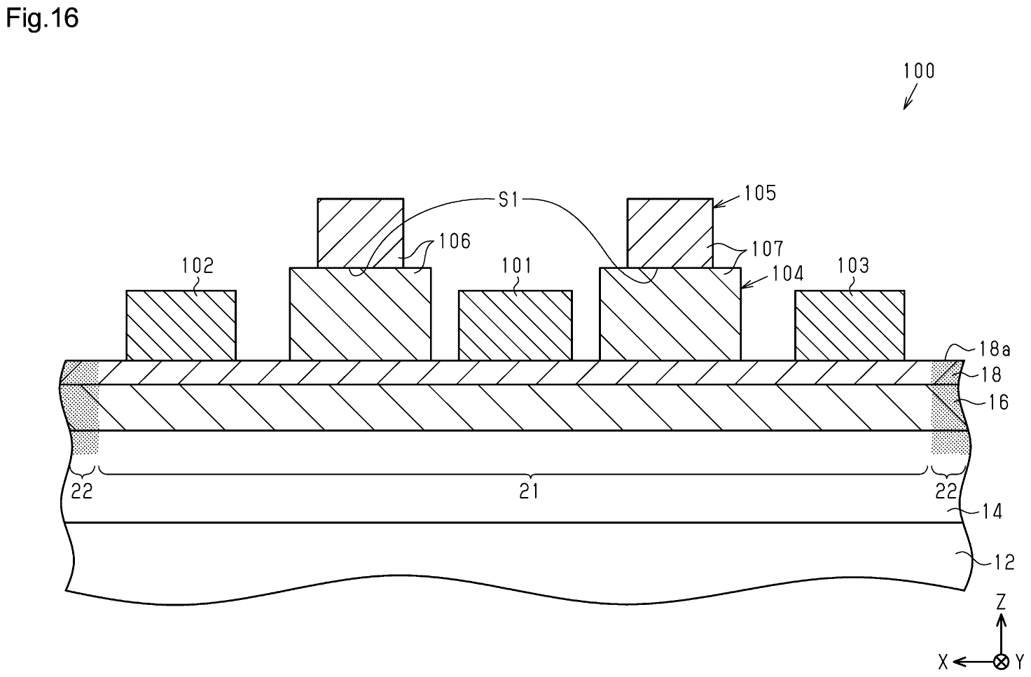

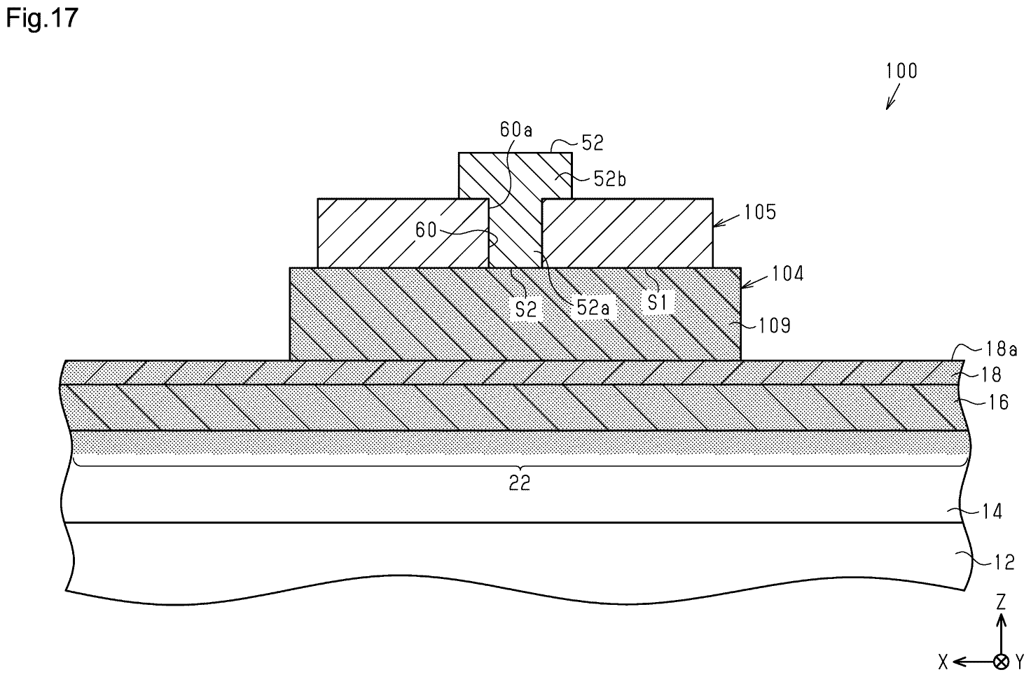

Modifications of the first embodiment will be described with reference to FIGS. 15 to 17. FIG. 15 is a schematic plan view of an exemplary nitride semiconductor device 100 according to a modification of the first embodiment. FIG. 16 is a schematic end view taken along line 16-16 in FIG. 15. FIG. 17 is a schematic end view taken along line 17-17 in FIG. 15.

As illustrated in FIGS. 15 and 16, in the present modification, the nitride semiconductor device 100 includes a source electrode 101 provided in the active region 21, and two drain electrodes 102 and 103 provided on the opposite sides, respectively, of the source electrode 101 in the X-axis direction.

Each of a gate layer 104 and a first gate electrode 105 of the present modification is formed in a frame shape surrounding the source electrode 101. Therefore, the source electrode 101 is disposed in frames of the gate layer 104 and the first gate electrode 105. On the other hand, the drain electrodes 102 and 103 are disposed outside the gate layer 104 and the first gate electrode 105.

In the present modification, two transistor cells are formed in the active region 21. That is, each of the gate layer 104 and the first gate electrode 105 includes a first gate portion 106 interposed between the source electrode 101 and the first drain electrode 102, and a second gate portion 107 interposed between the source electrode 101 and the second drain electrode 103. In other words, the source electrode 101, the first drain electrode 102, and the first gate portion 106 form a first transistor cell, and the source electrode 101, the second drain electrode 103, and the second gate portion 107 form a second transistor cell.

This configuration enables the integration of the nitride semiconductor device 100.

In the present modification, the gate layer 104 and the first gate electrode 105 are formed to extend over both the active region 21 and the inactive region 22. In particular, in the present modification, the gate layer 104 and the first gate electrode 105 are formed so as to overlap with a boundary between the active region 21 and the inactive region 22. Specifically, each of the gate layer 104 and the first gate electrode 105 includes a first coupling portion 108 coupling the first end portions of both the gate portions 106 and 107 with each other and a second coupling portion 109 coupling the second end portions of both the gate portions 106 and 107 with each other. Both the coupling portions 108 and 109 are disposed at positions, respectively, overlapping with the boundary between the active region 21 and the inactive region 22.

As illustrated in FIGS. 15 and 17, the opening 60 is formed in the first gate electrode 105. Similarly to the first embodiment, the opening 60 is formed at a position corresponding to the inactive region 22, specifically, in a portion above the inactive region 22 in the first gate electrode 105. The second gate electrode 52 is in contact with the upper surface of the gate layer 104 (specifically, the second parts 32) via the opening 60.

In the present modification, one opening 60 and one second gate electrode 52 are provided. That is, one second gate electrode 52 is shared by two transistor cells. This simplifies the configuration as compared with the configuration in which the second gate electrodes 52 are provided for the respective transistor cells. In addition, the ratio of the second contact area S2 to the first contact area S1 is further reduced, and through this, the gate leakage current is suppressed.

The opening 60 and the second gate electrode 52 are provided in the second coupling portion 109, but are not limited thereto, and may be provided in the first coupling portion 108 or may be provided in both the coupling portions 108 and 109.

According to the present modification described in detail above, the following advantages are exhibited.

(1-13) The gate layer 104 is formed in the frame shape surrounding the source electrode 101, and the drain electrodes 102 and 103 are disposed outside the gate layer 104. As a result, a leakage current from the drain electrodes 102 and 103 to the source electrode 101 is suppressed.

(1-14) The gate layer 104 is disposed at a position overlapping with the boundary between the active region 21 and the inactive region 22. As a result, the leakage current flowing from the drain electrodes 102 and 103 to the source electrode 101 via the boundary is suppressed.

### Wiring Line Structure in Modification of First Embodiment

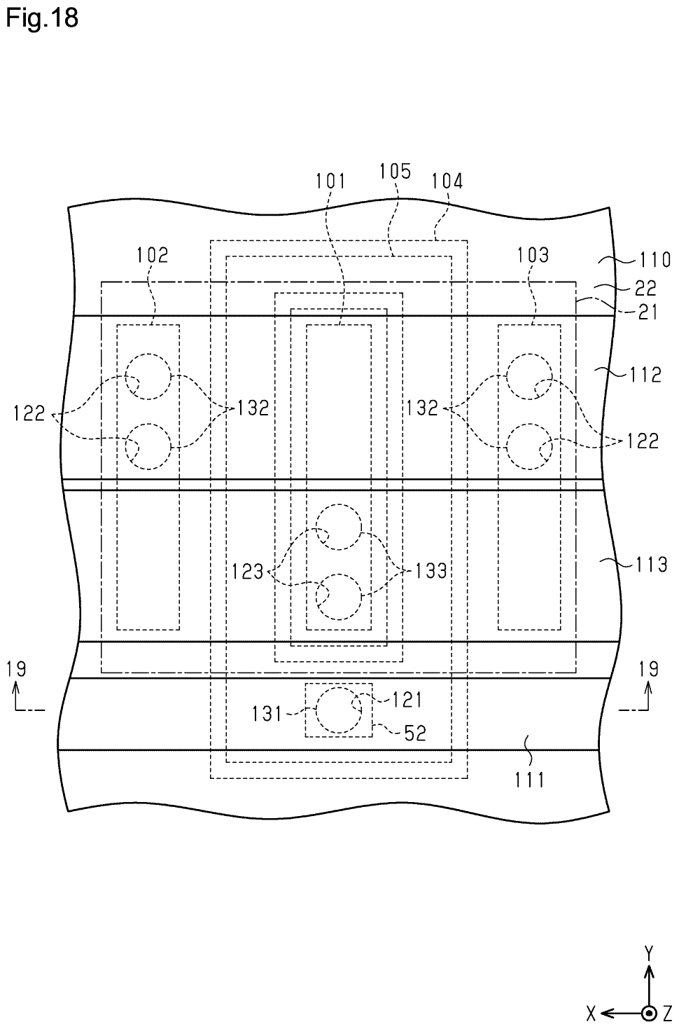

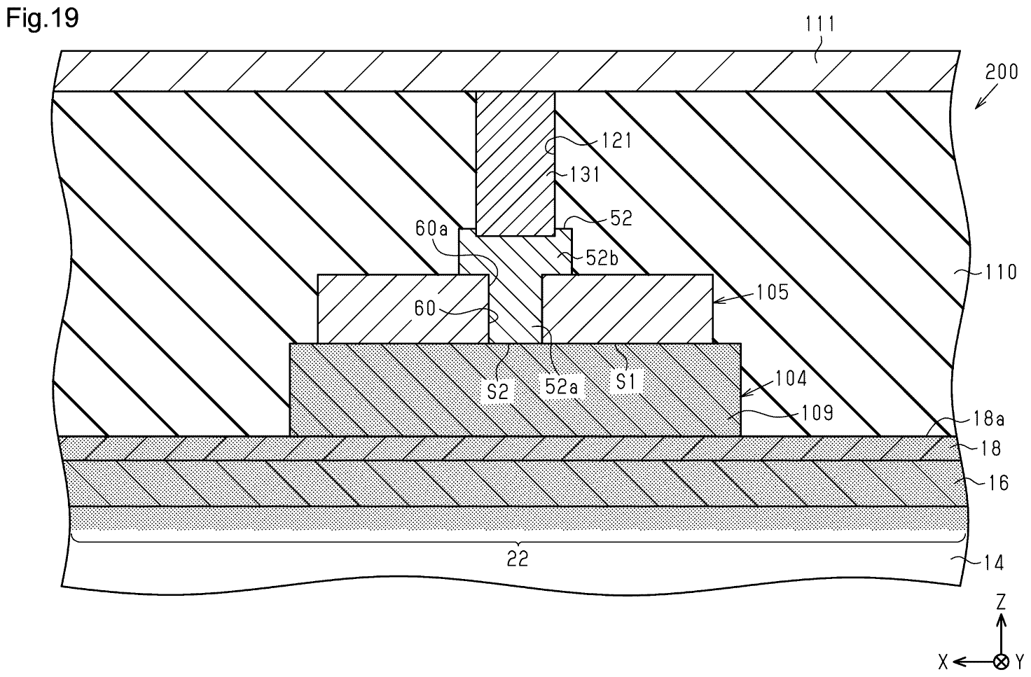

As illustrated in FIGS. 18 and 19, the nitride semiconductor device 100 may include a passivation film 110 covering the first gate electrode 105 and the second gate electrode 52, and wiring lines 111, 112, and 113 formed on the passivation film 110. The nitride semiconductor device 100 may include vias 121, 122, and 123, which are holes extending through the passivation film 110, and plugs 131, 132, and 133 embedded in the vias 121, 122, and 123, respectively.

The passivation film 110 has an insulating property. The passivation film 110 may be made of, for example, silicon nitride (SiN), silicon monoxide (SiO), silicon dioxide (SiO₂), or an organic material such as polyimide.

The wiring lines 111, 112, and 113 include, for example, a gate wiring line 111, a drain wiring line 112, and a source wiring line 113, respectively. The wiring lines 111, 112, and 113 are arranged apart from each other and insulated from each other. As one example, the wiring lines 111, 112, and 113 are arranged in the Y-axis direction. For example, the gate wiring line 111 is disposed at a position above the second gate electrode 52. The drain wiring line 112 is disposed at a position above both the drain electrodes 102 and 103. The source wiring line 113 is disposed at a position above the source electrode 101. The drain wiring line 112 and the source wiring line 113 are disposed at positions overlapping with the source electrode 101 and both the drain electrodes 102 and 103 and shifted from each other in the Y-axis direction.

The wiring lines 111, 112, and 113 are made of the same material. For example, the wiring lines 111, 112, and 113 may be made of Al, AlCu, or copper (Cu). This reduces the wiring line resistance.

The gate via 121 is disposed on the second gate electrode 52, and is a hole extending through the passivation film 110 in the thickness direction (in other words, the Z-axis direction) in order to electrically connect the second gate electrode 52 and the gate wiring line 111 to each other. In other words, the gate via 121 extends through the passivation film 110 to electrically connect the second gate electrode 52 and the gate wiring line 111 to each other. The gate via 121 may be formed to be smaller than the second gate electrode 52 in plan view, for example, and may be entirely contained in the second gate electrode 52.

Ti, Pd, or Ni may be used for the second gate electrode 52. In this case, the second gate electrode 52 is prevented from becoming thin when the gate via 121 is formed. More specifically, in the case of forming the gate via 121, it is conceivable to dry etch the passivation film 110. In this case, there is a concern that a part of the second gate electrode 52 is also etched by dry etching. In this regard, when Ti, Pd, and Ni are used as the second gate electrode 52, the second gate electrode 52 is relatively less likely to be dry-etched than the first gate electrode 105. Therefore, the second gate electrode 52 is prevented from becoming thin when forming the gate via 121. Therefore, the contact resistance between the gate wiring line 111 and the second gate electrode 52 is reduced, reducing the gate resistance.

Furthermore, as illustrated in FIG. 19, the gate plug 131 is embedded in the gate via 121. The gate plug 131 may be made of, for example, tungsten (W), may be made of another material, or may include an adhesion layer such as TiN that improves adhesion with the passivation film 110. The gate plug 131 electrically connects the second gate electrode 52 and the gate wiring line 111 to each other. That is, the first gate electrode 105 is electrically connected to the gate wiring line 111 via the second gate electrode 52 and the gate plug 131. By embedding the gate plug 131, the gate wiring line 111 is flattened. Further, by embedding the gate plug 131, for example, disconnection due to the gate via 121 is suppressed.

As illustrated in FIG. 18, the drain vias 122 are disposed on the drain electrodes 102 and 103, and are holes extending through the passivation film 110 in the thickness direction (in other words, the Z-axis direction) in order to electrically connect the drain electrodes 102 and 103 and the drain wiring line 112 to each other. The drain plug 132 is embedded in the drain via 122 and electrically connects the drain electrodes 102 and 103 and the drain wiring line 112 to each other. In other words, the drain via 122 extends through the passivation film 110 to electrically connect the drain electrodes 102 and 103 and the drain wiring line 112 to each other.

The source via 123 is disposed on the source electrode 101 and is a hole extending through the passivation film 110 in the thickness direction (in other words, the Z-axis direction) in order to electrically connect the source electrode 101 and the source wiring line 113 to each other. The source plug 133 is embedded in the source via 123 and electrically connects the source electrode 101 and the source wiring line 113 to each other. In other words, the source via 123 extends through the passivation film 110 to electrically connect the source electrode 101 and the source wiring line 113 to each other.

The shapes of the vias 121, 122, and 123 and the plugs 131, 132, and 133 may be circular in plan view. However, the example is not limited thereto, and the shapes of the vias 121, 122, and 123 and the plugs 131, 132, and 133 are arbitrary, and may be, for example, a rectangular shape or an oval shape. Instead of the plugs 131, 132, and 133, a part of each of the wiring lines 111, 112, and 113 may be embedded in a respective one of the vias 121, 122, and 123.

### Second Embodiment

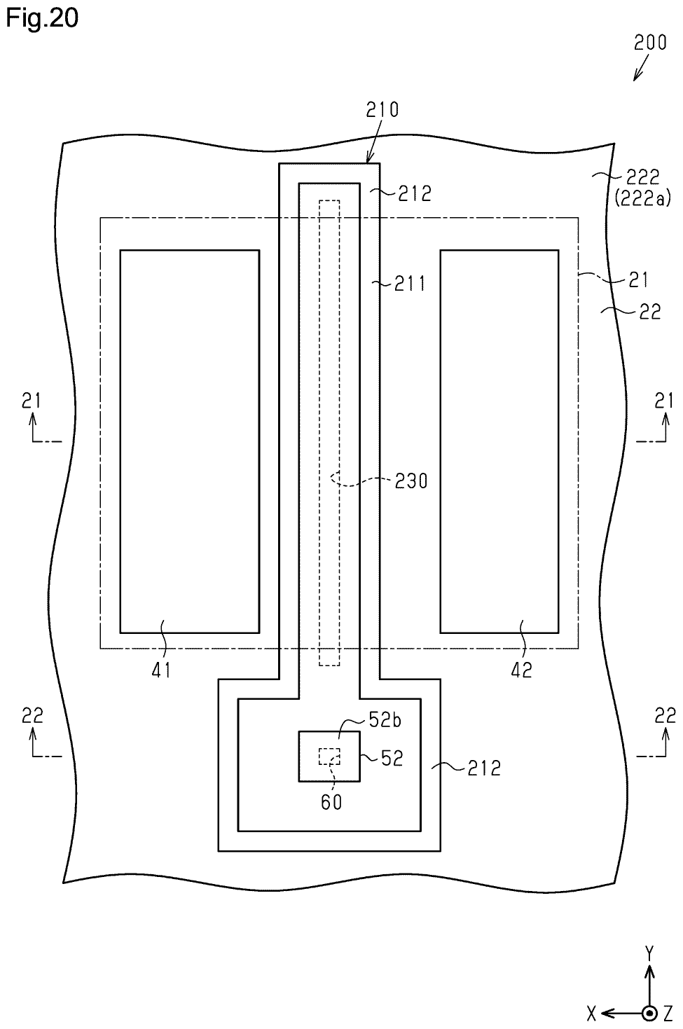

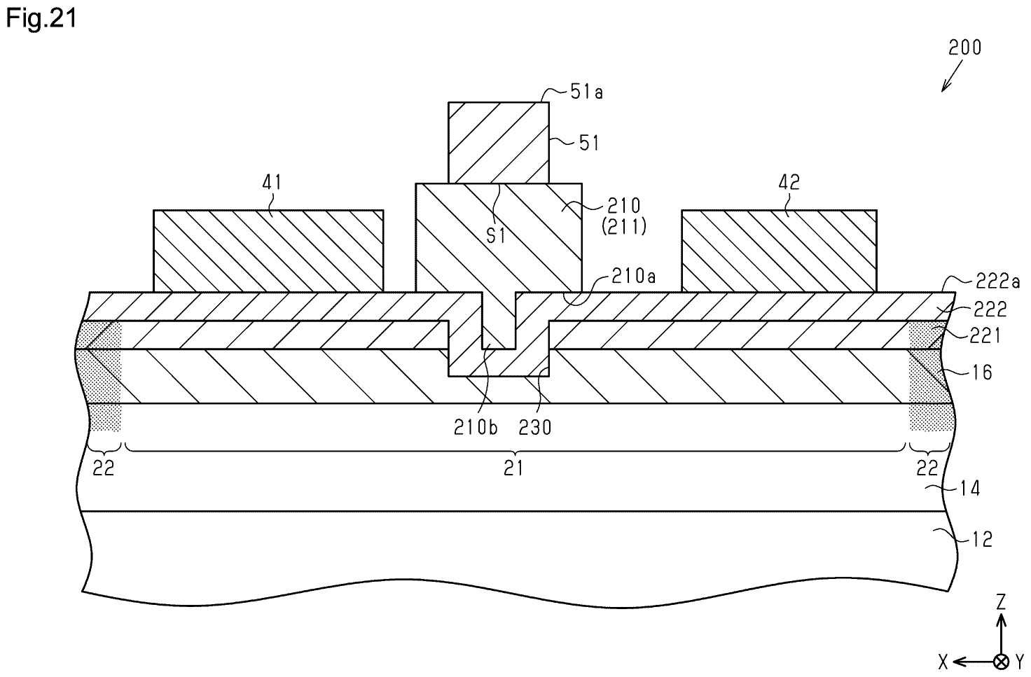

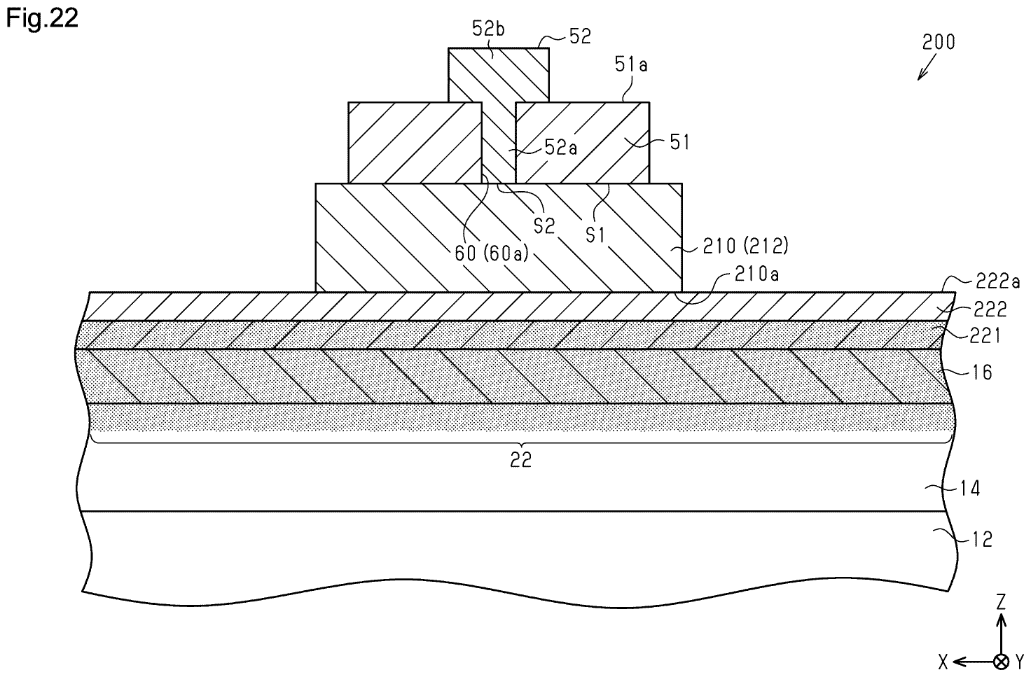

A second embodiment will be described with reference to FIGS. 20 to 22. FIG. 20 is a schematic plan view of an exemplary nitride semiconductor device 200 according to a second embodiment. FIG. 21 is a schematic cross-sectional view taken along line 21-21 in FIG. 20. FIG. 22 is a schematic cross-sectional view taken along line 22-22 in FIG. 21. As one example of the nitride semiconductor device 200, an HEMT using GaN will be described. The same reference numerals are given to the same configurations as those of the first embodiment, and the detailed description thereof will be omitted.

As illustrated in FIGS. 20 to 22, the nitride semiconductor device 200 according to the present embodiment includes a gate layer 210, a first electron supply layer 221, a second electron supply layer 222, and a recess region 230.

Similarly to the gate layer 30 of the first embodiment, the gate layer 210 of the present embodiment includes first parts 211 formed on the active region 21 and second parts 212 formed on the inactive region 22.

The gate layer 210 according to the present embodiment is configured to contain the acceptor impurity but not contain the impurity for making the 2DEG less likely to be generated. That is, the above-described impurity is not introduced into both the first parts 211 and the second parts 212 in the gate layer 210 of the present embodiment. Therefore, the second gate electrode 52 of the present embodiment forms a junction with the gate layer 210 into which the above-described impurity is not introduced.

The first electron supply layer 221 is similar to the electron supply layer 18 of the first embodiment, and is formed on the electron transit layer 16.

As illustrated in FIG. 21, the recess region 230 is formed in a lower portion of the gate layer 210. Specifically, the recess region 230 is formed in a region immediately below the first gate electrode 51 in the gate layer 210, but is not formed in a region immediately below the second gate electrode 52 in the gate layer 210. In the present embodiment, the recess region 230 is a recessed portion extending through the first electron supply layer 221 and reaching the electron transit layer 16.

As illustrated in FIG. 20, the recess region 230 is provided between the source electrode 41 and the drain electrode 42, and is formed so as to extend over both the active region 21 and the inactive region 22. Specifically, the recess region 230 extends in the Y-axis direction in a region immediately below the gate layer 210 and the first gate electrode 51 to traverse the active region 21. Therefore, the recess region 230 is also formed at a position overlapping with the boundary between the active region 21 and the inactive region 22.

The second electron supply layer 222 is made of a nitride semiconductor having a band gap larger than a band gap of the electron transit layer 16. For example, the second electron supply layer 222 may be made of the same material as the first electron supply layer 221. As one example, the second electron supply layer 222 may be AlGaN.

In a case where the first electron supply layer 221 and the second electron supply layer 222 are made of the same material (for example, AlGaN), composition ratios thereof may be the same. As a result, carriers due to polarization are generated between the electron supply layers 221 and 222, and leakage currents between the gate and the source and between the gate and the drain are be suppressed. However, the example is not limited thereto, and composition ratios of the electron supply layers 221 and 222 may be different from each other.

As illustrated in FIG. 21, the second electron supply layer 222 is provided to extend over both the recess region 230 and the first electron supply layer 221. Specifically, the second electron supply layer 222 is formed on the first electron supply layer 221. The second electron supply layer 222 is formed on a bottom surface and side surfaces of the recess region 230. As a result, a space surrounded by the second electron supply layer 222 is formed in the recess region 230. In other words, the second electron supply layer 222 is formed so as to fill a part in the recess region 230.

The first electron supply layer 221 and the second electron supply layer 222 are disposed between the gate layer 210 and the drain electrode 42. Similarly, the first electron supply layer 221 and the second electron supply layer 222 are disposed between the gate layer 210 and the source electrode 41. That is, as compared with the first embodiment, the thickness of the electron supply layer between the gate layer 210 and the drain electrode 42 is increased and the thickness of the electron supply layer between the gate layer 210 and the source electrode 41 is increased by the second electron supply layer 222.

In the present embodiment, the second electron supply layer 222 formed on the inactive region 22 does not contain the impurity that inhibits the generation of the 2DEG.

However, the example is not limited thereto, and the second electron supply layer 222 formed on the inactive region 22 may contain the above-described impurity.

The gate layer 210 of the present embodiment includes a bottom surface 210a in contact with an upper surface 222a of the second electron supply layer 222, and a protrusion 210b protruding from the bottom surface 210a toward the electron transit layer 16. The protrusion 210b is disposed in the recess region 230 and fills the space surrounded by the second electron supply layer 222 in the recess region 230. The protrusion 210b is in contact with the second electron supply layer 222 present in the recess region 230.

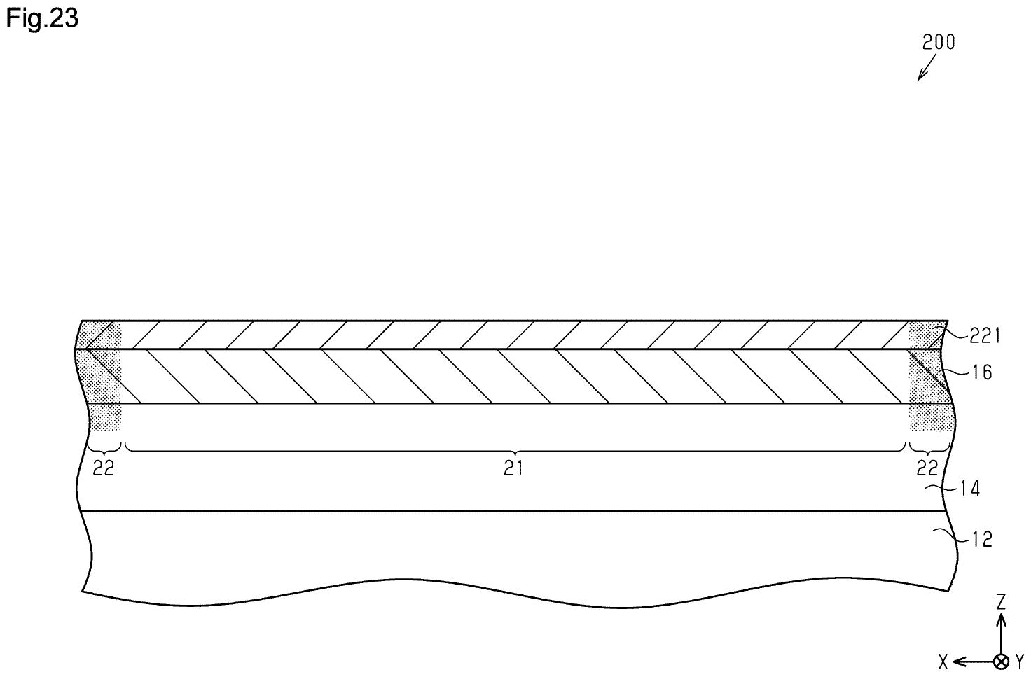

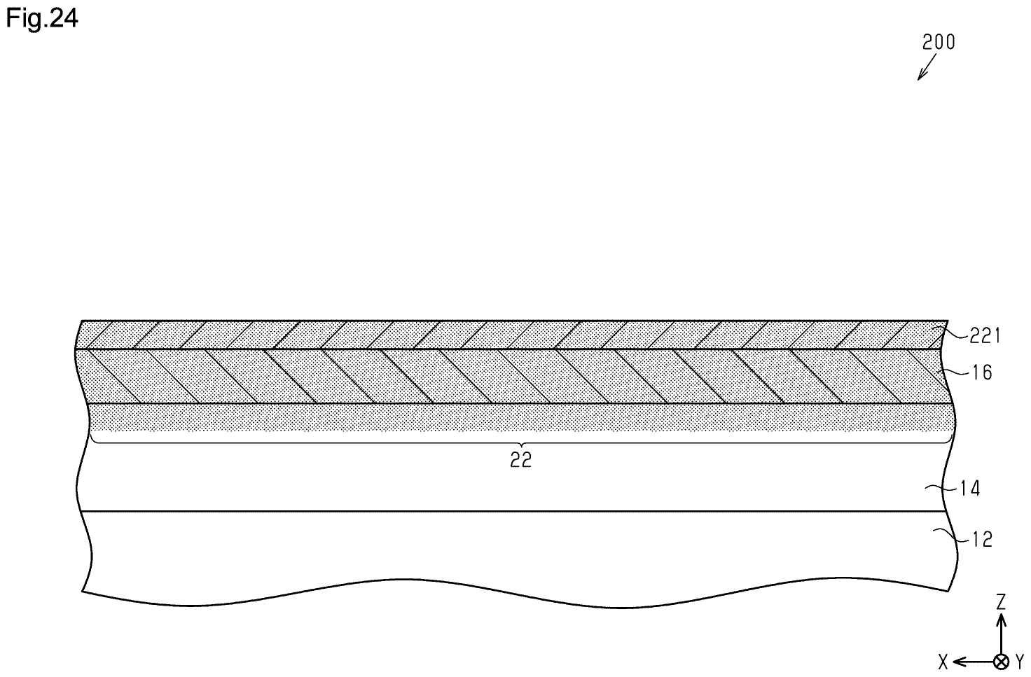

Next, a method for manufacturing the nitride semiconductor device 200 according to the present embodiment will be described with reference to FIGS. 23 to 34. Each of FIGS. 23, 25, 27, 29, 31, and 33 is a schematic cross-sectional view taken along line 21-21 of a respective one of the steps, and each of FIGS. 24, 26, 28, 30, 32, and 34 is a schematic cross-sectional view taken along line 22-22 of a respective one of the steps.

The method for manufacturing the nitride semiconductor device 200 according to the present embodiment includes a step of forming the buffer layer 14, the electron transit layer 16, and the first electron supply layer 221 on the semiconductor substrate 12. This step uses epitaxial growth by MOCVD, for example.

As illustrated in FIGS. 23 and 24, the method for manufacturing the nitride semiconductor device 200 includes a step of forming the inactive region 22 after the first electron supply layer 221 is formed. That is, in the present embodiment, the inactive region 22 is formed before the gate layer 210 is formed. A specific method of this step is the same as the first embodiment.

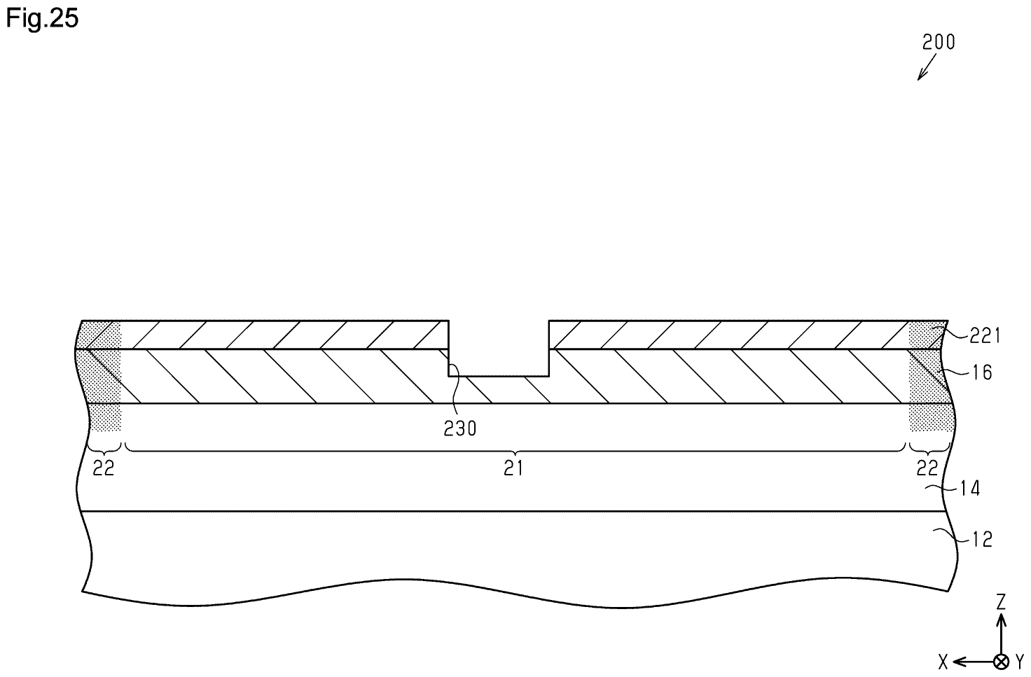

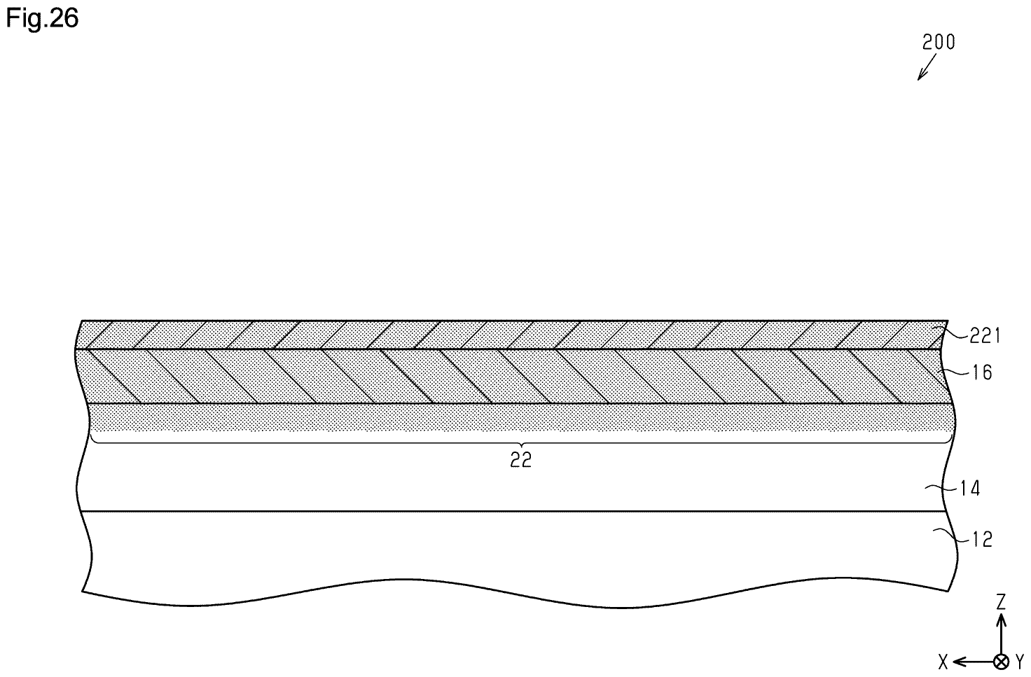

As illustrated in FIG. 25, the method for manufacturing the nitride semiconductor device 200 includes a step of forming the recess region 230. In this step, it is conceivable to use, for example, dry etching. As illustrated in FIG. 26, the recess region 230 is not formed in a place where the second gate electrode 52 is formed.

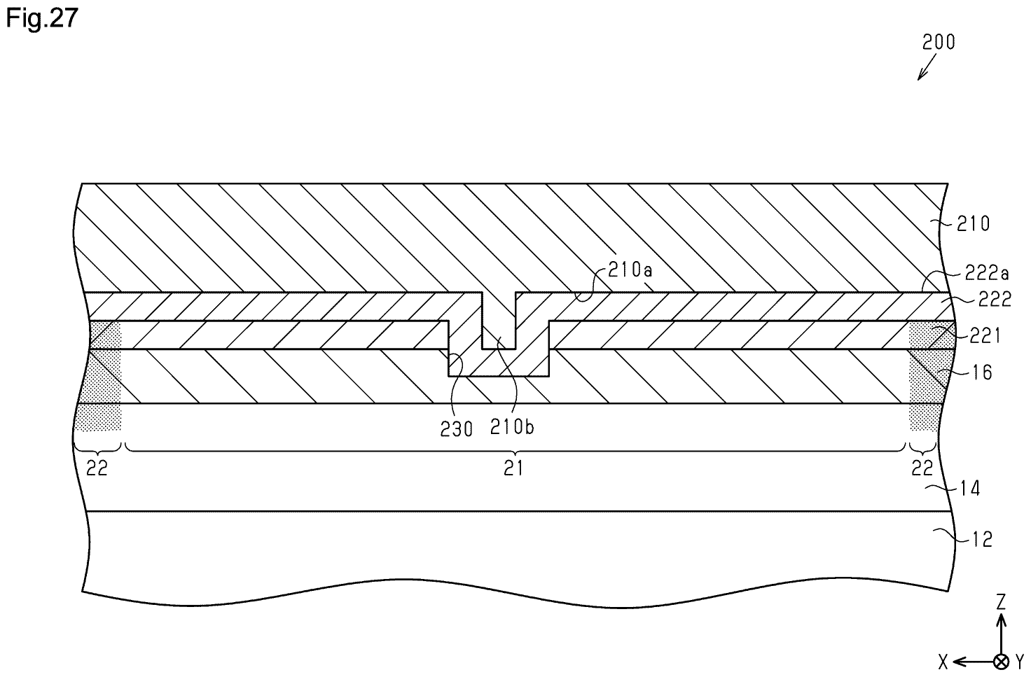

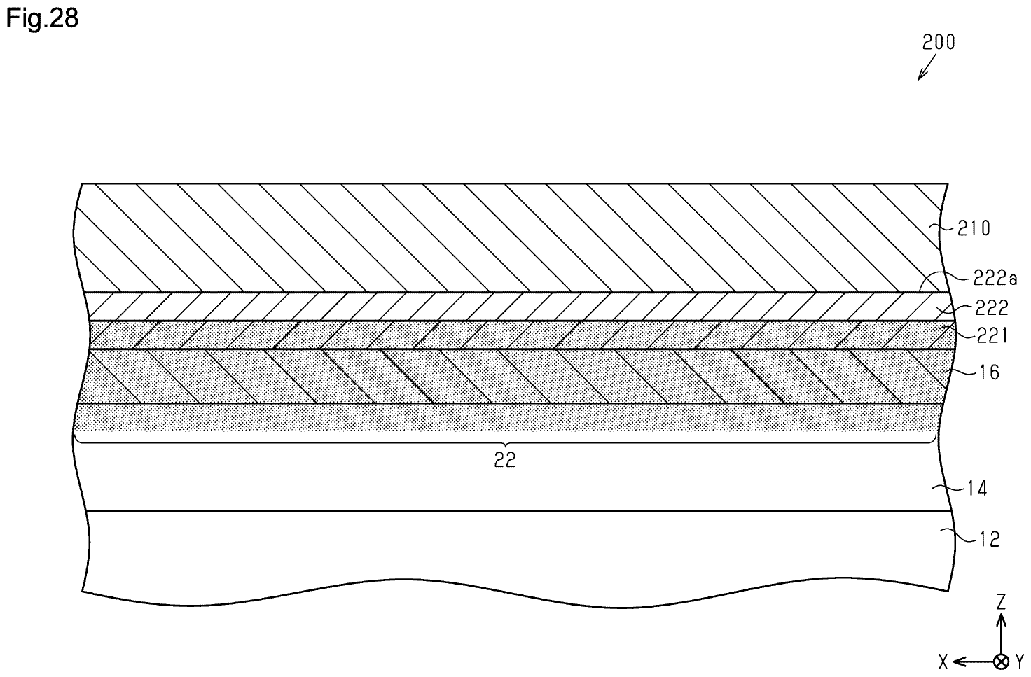

As illustrated in FIGS. 27 and 28, the method for manufacturing the nitride semiconductor device 200 includes a step of forming the second electron supply layer 222 and a step of forming the gate layer 210 after forming the second electron supply layer 222. In the steps of forming the second electron supply layer 222 and the gate layer 210, it is conceivable to perform, for example, regrowth by MOCVD. In this case, the second electron supply layer 222 and the gate layer 210 are embedded in the recess region 230 by regrowing the gate layer 210 after the second electron supply layer 222 is regrown. In particular, in the step of forming the second electron supply layer 222, the film thickness of the second electron supply layer 222 is preferably adjusted so that a desired 2DEG concentration is achieved.

In the present embodiment, the gate layer 210 is formed after the step of forming the inactive region 22. Therefore, the gate layer 210 does not contain the impurity for making the 2DEG less likely to be generated.

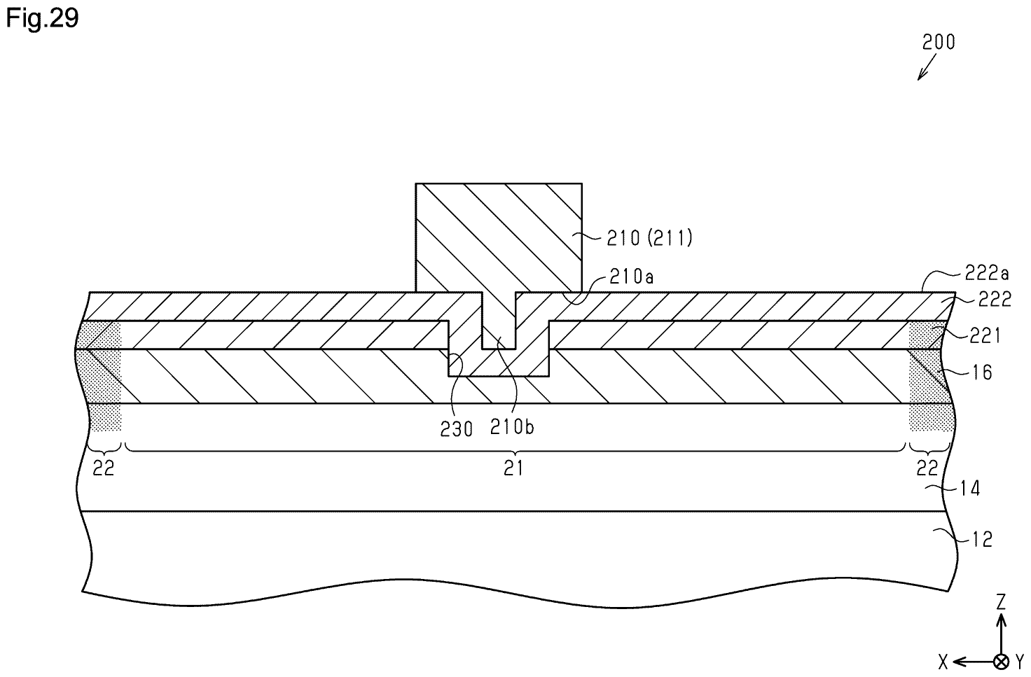

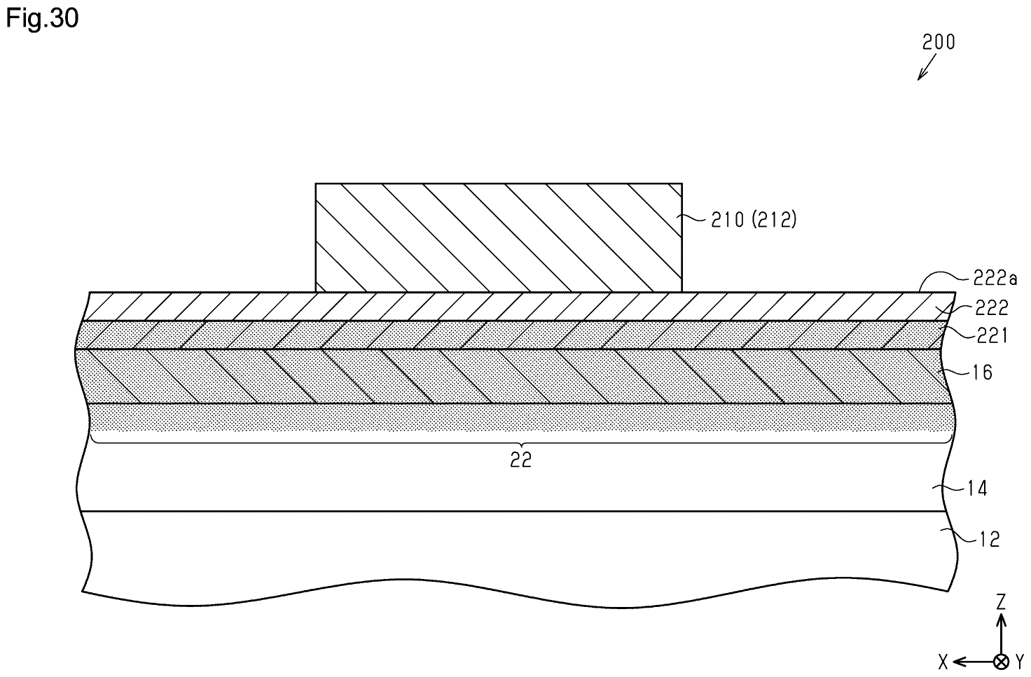

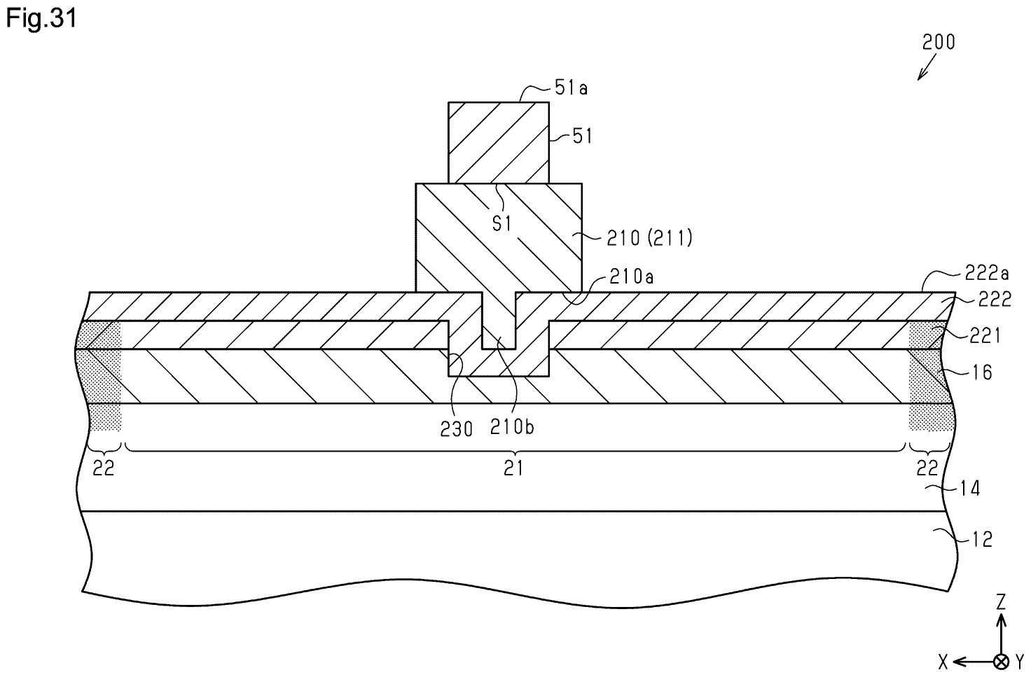

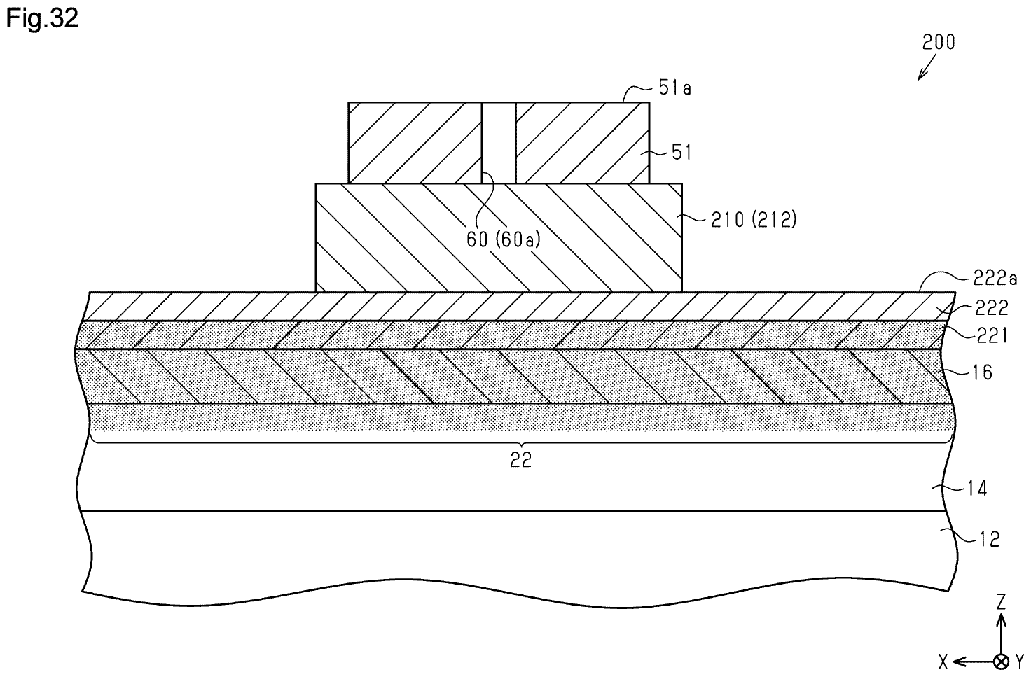

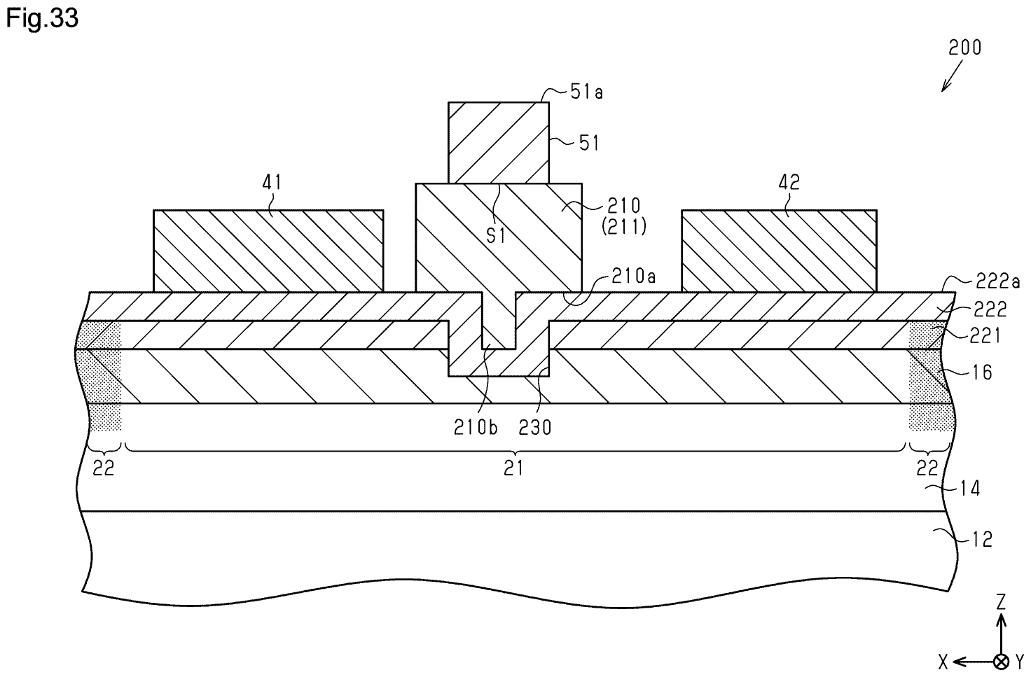

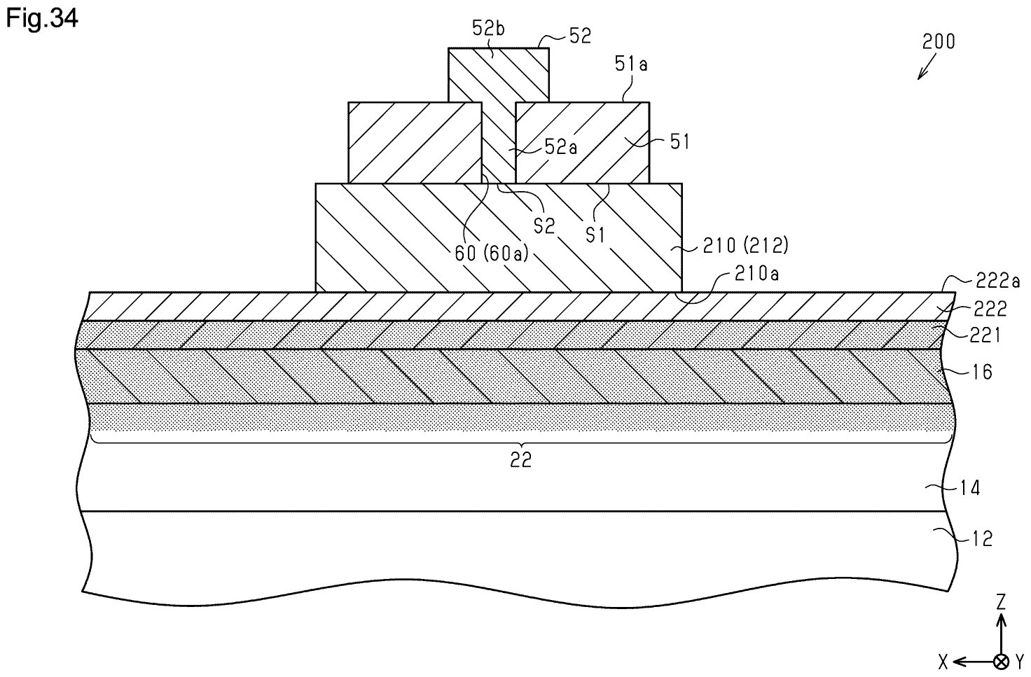

As illustrated in FIGS. 29 and 30, the method for manufacturing the nitride semiconductor device 200 includes a step of etching the gate layer 210. As illustrated in FIGS. 31 and 32, the method for manufacturing the nitride semiconductor device 200 includes a step of forming the first gate electrode 51. As illustrated in FIGS. 33 and 34, the method for manufacturing the nitride semiconductor device 200 includes a step of forming the second gate electrode 52, the source electrode 41, and the drain electrode 42. These steps are similar to those of the first embodiment, and thus detailed description thereof is omitted.

According to the present embodiment described in detail above, the following advantages are exhibited in addition to the advantages of the first embodiment.

(2-1) A portion of the gate layer 210 in contact with the second gate electrode 52 (in other words, the second parts 212) contains the acceptor impurity but does not contain the impurity contained in the inactive region 22. As a result, the Schottky barrier between the second gate electrode 52 and the gate layer 210 is reduced. Alternatively, the second gate electrode 52 and the gate layer 210 can form the ohmic junction. Therefore, a potential of the gate layer 210 is prevented from floating, and the potential of the gate layer 210 is stabilized. Therefore, the fluctuation of the threshold voltage caused by the gate layer 210 is further suppressed.

(2-2) The nitride semiconductor device 200 includes the recess region 230 provided in the lower portion of the gate layer 210, extending through the first electron supply layer 221, and reaching the electron transit layer 16, and the second electron supply layer 222 provided to extend over both the recess region 230 and the first electron supply layer 221. The gate layer 210 includes the bottom surface 210a in contact with the upper surface 222a of the second electron supply layer 222, and the protrusion 210b protruding from the bottom surface 210a toward the electron transit layer 16. The protrusion 210b is disposed in the recess region 230 and is in contact with the second electron supply layer 222.

According to such a configuration, the first electron supply layer 221 immediately below the gate layer 210 is removed by the recess region 230. As a result, the concentration of the 2DEG generated immediately below the gate layer 210 can be controlled by controlling the film thickness of the second electron supply layer 222. Therefore, the threshold voltage can be readily controlled. In addition, the leakage current between the source and the drain is less likely to flow by the recess region 230 immediately below the gate layer 210. As a result, the leakage current between the source and the drain is suppressed.

In addition, since the second electron supply layer 222 is provided, as compared with the configuration in which only the first electron supply layer 221 is provided, the 2DEG generation regions between the gate layer 210 and the source electrode 41 and between the gate layer 210 and the drain electrode 42 are separated from the semiconductor surface (the upper surface 222a of the second electron supply layer 222). As a result, the influence of the depletion layer from the semiconductor surface is reduced, so that the concentration of the 2DEG is increased. Therefore, the on-resistance is reduced.

### Modification of Second Embodiment

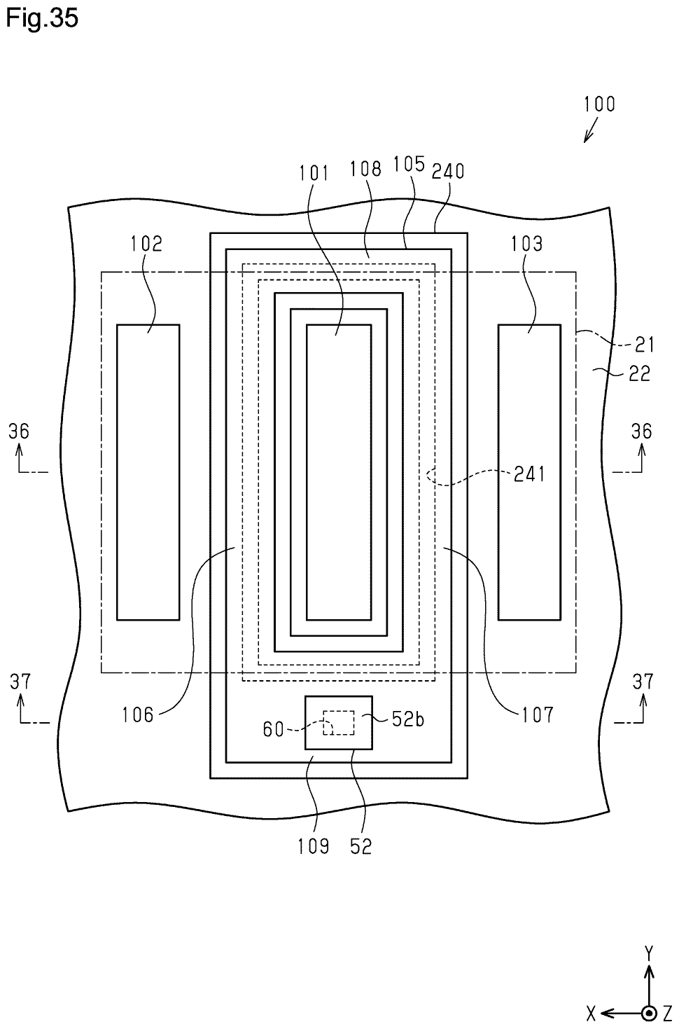

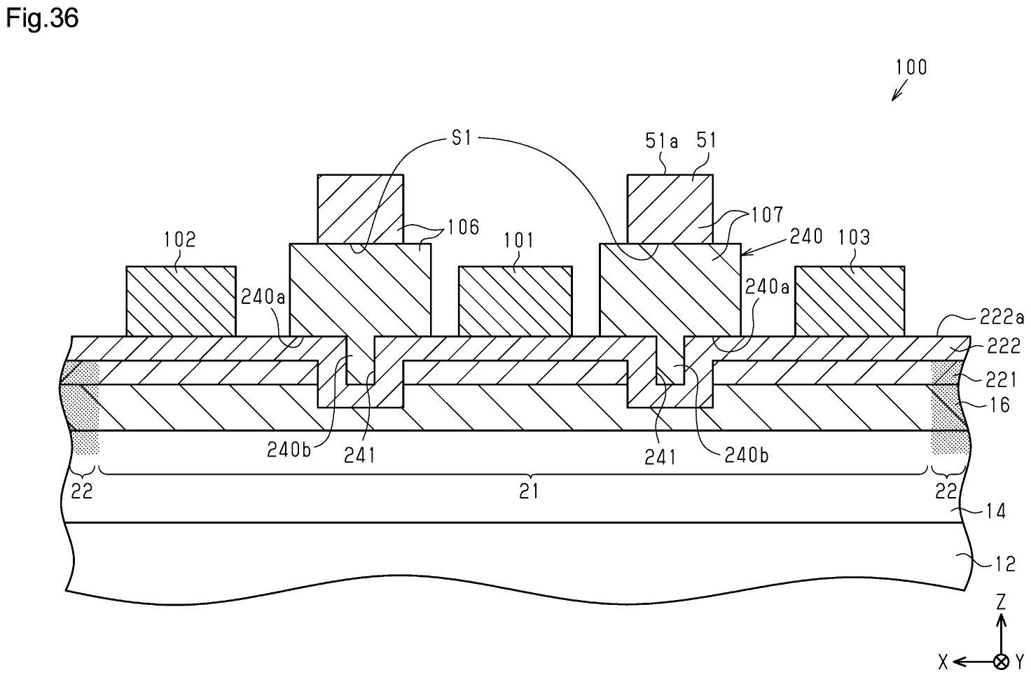

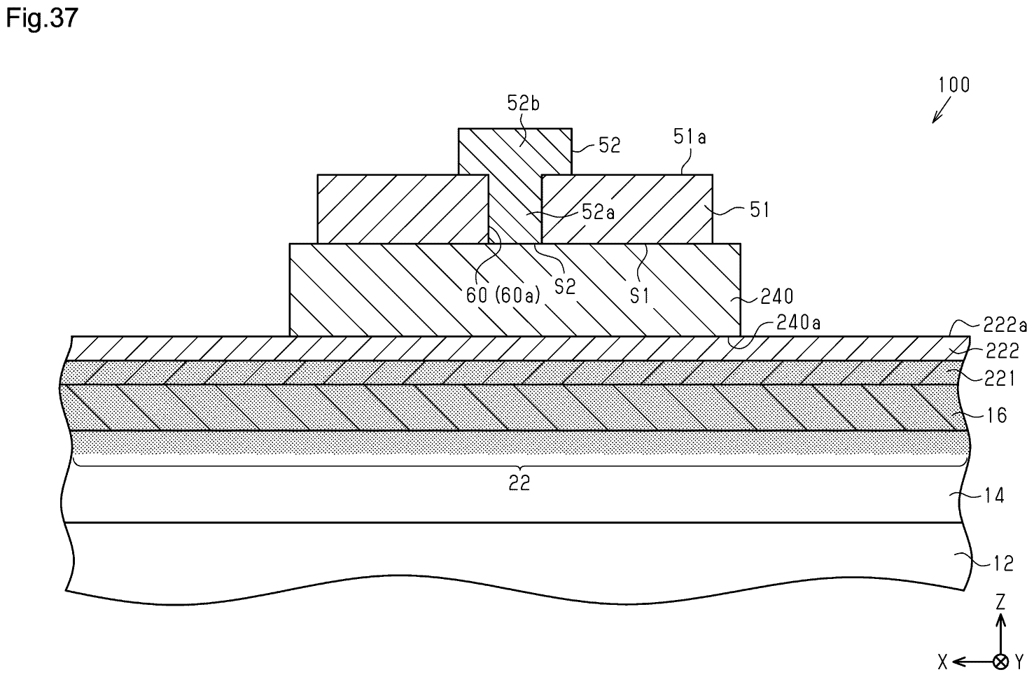

As illustrated in FIGS. 35 to 37, in the configuration in which the source electrode 101 and the drain electrodes 102 and 103 are formed, the gate layer 240 and first gate electrode 105 may be formed in the frame shape surrounding the source electrode 101. In this case, the recess region 241 may also be formed in the frame shape surrounding the source electrode 101. The gate layer 240, the first gate electrode 105, and the recess region 241 are preferably disposed at a position overlapping with the boundary between the active region 21 and the inactive region 22. As a result, the leakage current via the boundary is suppressed.

The gate layer 240 may include the bottom surface 240a and the protrusion 240b protruding from the bottom surface 240a. The protrusion 240b may be formed in a protruding shape having the frame shape corresponding to the recess region 241.

### Other Modifications

The above embodiments and modifications may be modified as described below. The above embodiments and the modifications may be combined as long as there is no technical contradiction. In the modifications described hereafter, same reference characters are given to those components that are the same as the corresponding components of the above embodiments. Such components will not be described in detail.

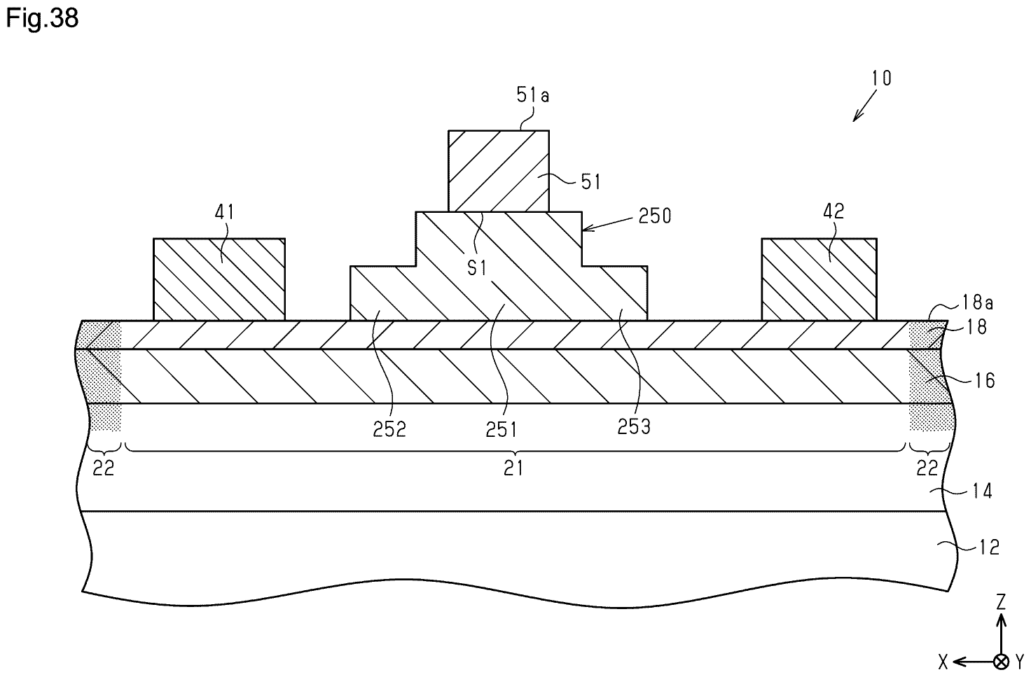

The shape of the gate layer 30 may be modified. For example, as illustrated in FIG. 38, the gate layer 30 may include a ridge portion 251, a source extending portion 252 extending from the ridge portion 251 toward the source electrode 41, and a drain extending portion 253 extending from the ridge portion 251 toward the drain electrode 42. The extending portions 252 and 253 are thinner than the ridge portion 251. In addition, a gate layer 250 may have a configuration including only one of the extending portions 252 and 253.

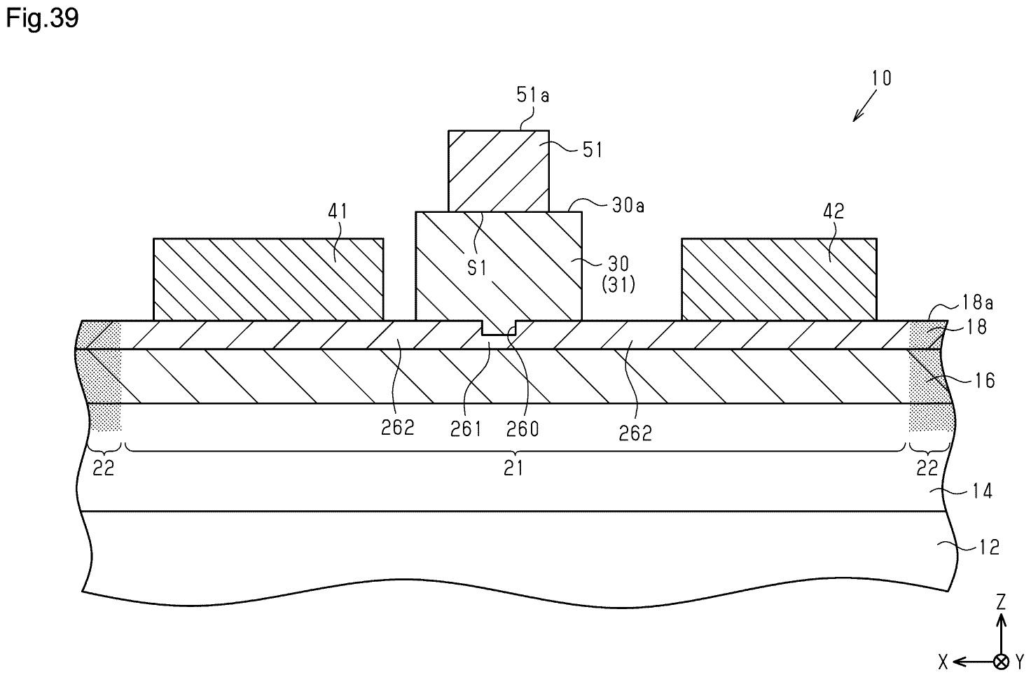

As illustrated in FIG. 39, the nitride semiconductor device 10 may include a recess region 260 recessed from the upper surface 18a of the electron supply layer 18. The recess region 260 is preferably provided in a portion of the electron supply layer 18 overlapping with the gate layer 30. The recess region 260 need not extend through the electron supply layer 18. In other words, the recess region 260 may partially thin the electron supply layer 18. In this case, the electron supply layer 18 includes a thin film portion 261 and a thick film portion 262 by the recess region 260. The thin film portion 261 is formed in a region immediately below the gate layer 30 and the first gate electrode 51. The thick film portion 262 is formed in a region between the gate layer 30 and the source electrode 41 and a region between the gate layer 30 and the drain electrode 42. As a result, the leakage current is suppressed by suppressing the generation of the 2DEG immediately below the thin film portion 261. In addition, the on-resistance is reduced by improving the concentration of the 2DEG in the region between the gate layer 30 and the source electrode 41 and the region between the gate layer 30 and the drain electrode 42.

The source electrodes 41 and 101 may include a source field plate portion.

The embedded portion 52a and the overlap portion 52b may be made of different materials. In the second gate electrode 52, at least a portion in contact with the gate layer 30 may be made of a material having a work function higher than that of the first gate electrode 51.

In the present disclosure, the term “on” includes the meaning of “above” in addition to the meaning of “on” unless otherwise clearly indicated in the context. Thus, the phrase “element A is formed on element B” is intended to mean that element A may be disposed directly on element B in contact with element B in one embodiment and also that element A may be disposed above element B without contacting element B in another embodiment. In other words, the term “on” does not exclude a structure in which another element is formed between element A and element B.

The Z-direction referred to in the present disclosure does not necessarily have to be the vertical direction and does not necessarily have to exactly coincide with the vertical direction. Accordingly, in the structures of the present disclosure, “up” and “down” in the z-direction as referred to in this specification is not limited to “up” and “down” in the vertical direction. For example, the X-direction may be the vertical direction.

Alternatively, the Y-direction may be the vertical direction.

In this specification, “at least one of A and B” should be understood to mean “only A, only B, or both A and B.”

Terms such as “first”, “second”, and “third” in this disclosure are used to distinguish subjects and not used for ordinal purposes.

### CLAUSES

Technical concepts that can be understood from each of the above embodiments and modifications will now be described. For aid in understanding and not for limitation, the reference numerals of corresponding components in the embodiment are given to components described in the clauses. The reference numerals are given as examples to aid understanding, and the components described in each clause should not be limited to the components indicated by the reference numerals.

### Clause 1

A nitride semiconductor device, including:
an electron transit layer (16) made of a nitride semiconductor;
an electron supply layer (18 and 221) formed on the electron transit layer and made of a nitride semiconductor having a larger band gap than that of the electron transit layer;
a gate layer (30, 104, 210, 240, and 250) formed on the electron supply layer and made of a nitride semiconductor containing an acceptor impurity;
a first gate electrode (51 and 105) in contact with an upper surface of the gate layer;
a source electrode (41 and 101) and a drain electrode (42, 102, and 103) disposed so as to sandwich the gate layer and in contact with an upper surface of the electron supply layer; and
a second gate electrode (52) made of a material different from the first gate electrode and in contact with the upper surface of the gate layer,
in which a second contact area (S2), which is a contact area between the second gate electrode and the gate layer, is smaller than a first contact area (S1), which is a contact area between the first gate electrode and the gate layer.

### Clause 2

The nitride semiconductor device according to clause 1, in which the second gate electrode is made of a material having a higher work function than that of the first gate electrode.

### Clause 3

The nitride semiconductor device according to clause 1 or 2, in which the second gate electrode is configured to form an ohmic junction with the gate layer.

### Clause 4

The nitride semiconductor device according to any one of clauses 1 to 3, in which the second gate electrode contains any of Ti, Pd, and Ni.

### Clause 5

The nitride semiconductor device according to any one of clauses 1 to 4, in which the second gate electrode is made of the same material as the source electrode and the drain electrode.

### Clause 6

The nitride semiconductor device according to any one of clauses 1 to 5, in which the second contact area is 1/100 or less of the first contact area.

### Clause 7

The nitride semiconductor device according to any one of clauses 1 to 6, in which the first gate electrode is configured to form a Schottky junction with the gate layer.

### Clause 8

The nitride semiconductor device according to any one of clauses 1 to 7, in which the first gate electrode contains any of TiN, TaN, WN, TiSiN, TaSiN, WSi, and WSiN.

### Clause 9

The nitride semiconductor device according to any one of clauses 1 to 8, in which
each of the electron transit layer and the electron supply layer includes
   an active region (21) where a two-dimensional electron gas is generated, and
   an inactive region (22) where the two-dimensional electron gas is less likely to be generated than in the active region, the gate layer includes
   a first part (31 and 211) formed on the active region, and
   a second part (32 and 212) formed on the inactive region, at least a part of the first gate electrode is formed on the first part, and the second gate electrode is formed on the second part.

### Clause 10

The nitride semiconductor device according to clause 9, in which the inactive region contains an impurity configured to make the two-dimensional electron gas less likely to be generated.

### Clause 11

The nitride semiconductor device according to clause 10, in which the impurity configured to make the two-dimensional electron gas less likely to be generated includes any of He, B, N, O, F, and Ar.

### Clause 12

The nitride semiconductor device according to any one of clauses 9 to 11, in which the second part contains an impurity configured to make the two-dimensional electron gas less likely to be generated.

### Clause 13

The nitride semiconductor device according to any one of clauses 9 to 11, in which the second part does not contain an impurity configured to make the two-dimensional electron gas less likely to be generated.

### Clause 14

The nitride semiconductor device according to any one of clauses 1 to 13, in which
the first gate electrode includes an opening (60) configured to expose the gate layer, and
the second gate electrode includes an embedded portion (52a) embedded in the opening and in contact with the gate layer.

### Clause 15

The nitride semiconductor device according to clause 14, in which
the embedded portion is in contact with a side surface (60a) of the opening of the first gate electrode, and
the second gate electrode includes an overlap portion (52b) formed to be wider than the opening in plan view and in contact with an upper surface of the first gate electrode.

### Clause 16

The nitride semiconductor device according to any one of clauses 1 to 15, in which
the gate layer is formed in a frame shape surrounding the source electrode, and
the drain electrode is disposed outside the gate layer.

### Clause 17

The nitride semiconductor device according to any one of clauses 1 to 16, in which
a portion of the electron supply layer, the portion overlapping with the gate layer, includes a recess region (260) recessed from an upper surface of the electron supply layer, and
the electron supply layer includes
   a thin film portion (261) thinned by the recess region, and
   a thick film portion (262) thicker than the thin film portion.

### Clause 18

The nitride semiconductor device according to any one of clauses 1 to 16, in which
the electron supply layer is a first electron supply layer (221),
a lower portion of the gate layer includes a recess region (230 and 241) extending through the first electron supply layer and reaching the electron transit layer,
the nitride semiconductor device includes a second electron supply layer (222) made of a nitride semiconductor having a band gap larger than that of the electron transit layer,
the second electron supply layer is provided to extend over both the recess region and the first electron supply layer,
the gate layer includes
   a bottom surface (210a) in contact with an upper surface of the second electron supply layer, and
   a protrusion (210b) protruding from the bottom surface toward the electron transit layer, and
   the protrusion is disposed in the recess region and is in contact with the second electron supply layer.

### Clause 19

The nitride semiconductor device according to clause 18, in which the second electron supply layer is made of the same material as the first electron supply layer.

Clause 20 The nitride semiconductor device according to any one of clauses 17 to 19, in which
each of the electron transit layer and the electron supply layer includes:
   an active region (21) where a two-dimensional electron gas is generated, and
   an inactive region (22) where the two-dimensional electron gas is less likely to be generated than in the active region,
the gate layer is formed to extend over both the active region and the inactive region, and
the recess region is provided between the source electrode and the drain electrode and is formed to extend over both the active region and the inactive region.

### Clause 21

The nitride semiconductor device according to any one of clauses 1 to 20, further including
an insulating passivation film (110) covering the first gate electrode and the second gate electrode,
a gate wiring line (111) formed on the passivation film, and
a gate via (121) extending through the passivation film and configured to electrically connect the second gate electrode and the gate wiring line to each other.

### Clause 22

The nitride semiconductor device according to clause 21, further including a gate plug (131) embedded in the gate via.

Various changes in form and details may be made to the examples above without departing from the spirit and scope of the claims and their equivalents. The examples are for the sake of description only, and not for purposes of limitation. Descriptions of features in each example are to be considered as being applicable to similar features or aspects in other examples. Suitable results may be achieved if sequences are performed in a different order, and/or if components in a described system, architecture, device, or circuit are combined differently, and/or replaced or supplemented by other components or their equivalents. The scope of the disclosure is not defined by the detailed description, but by the claims and their equivalents. All variations within the scope of the claims and their equivalents are included in the disclosure.

What is claimed is:

1. A nitride semiconductor device, comprising:
an electron transit layer made of a nitride semiconductor;
an electron supply layer formed on the electron transit layer and made of a nitride semiconductor having a larger band gap than that of the electron transit layer;
a gate layer formed on the electron supply layer and made of a nitride semiconductor containing an acceptor impurity;
a first gate electrode in contact with an upper surface of the gate layer;
a source electrode and a drain electrode disposed so as to sandwich the gate layer and in contact with an upper surface of the electron supply layer; and
a second gate electrode made of a material different from the first gate electrode and in contact with the upper surface of the gate layer,
wherein a second contact area, which is a contact area between the second gate electrode and the gate layer, is smaller than a first contact area, which is a contact area between the first gate electrode and the gate layer.

2. The nitride semiconductor device according to claim 1, wherein the second gate electrode is made of a material having a higher work function than that of the first gate electrode.

3. The nitride semiconductor device according to claim 2, wherein the second gate electrode is configured to form an ohmic junction with the gate layer.

4. The nitride semiconductor device according to claim 2, wherein the second gate electrode contains any of Ti, Pd, and Ni.

5. The nitride semiconductor device according to claim 1, wherein the second gate electrode is made of the same material as the source electrode and the drain electrode.

6. The nitride semiconductor device according to claim 1, wherein the second contact area is 1/100 or less of the first contact area.

7. The nitride semiconductor device according to claim 1, wherein the first gate electrode is configured to form a Schottky junction with the gate layer.

8. The nitride semiconductor device according to claim 1, wherein the first gate electrode contains any of TiN, TaN, WN, TiSiN, TaSiN, WSi, and WSiN.

9. The nitride semiconductor device according to claim 1, wherein
each of the electron transit layer and the electron supply layer includes
an active region where a two-dimensional electron gas is generated, and
an inactive region where the two-dimensional electron gas is less likely to be generated than in the active region,
the gate layer includes
a first part formed on the active region, and
a second part formed on the inactive region,
at least a part of the first gate electrode is formed on the first part, and
the second gate electrode is formed on the second part.

10. The nitride semiconductor device according to claim 9, wherein the inactive region contains an impurity configured to make the two-dimensional electron gas less likely to be generated.

11. The nitride semiconductor device according to claim 10, wherein the impurity configured to make the two-dimensional electron gas less likely to be generated includes any of He, B, N, O, F, and Ar.

12. The nitride semiconductor device according to claim 1, wherein
the first gate electrode includes an opening configured to expose the gate layer, and
the second gate electrode includes an embedded portion embedded in the opening and in contact with the gate layer.

13. The nitride semiconductor device according to claim 12, wherein
the embedded portion is in contact with a side surface of the opening of the first gate electrode, and
the second gate electrode includes an overlap portion formed to be wider than the opening in plan view and in contact with an upper surface of the first gate electrode.

14. The nitride semiconductor device according to claim 1, wherein
the gate layer is formed in a frame shape surrounding the source electrode, and
the drain electrode is disposed outside the gate layer.

15. The nitride semiconductor device according to claim 1, wherein
a portion of the electron supply layer, the portion overlapping with the gate layer, includes a recess region recessed from an upper surface of the electron supply layer, and
the electron supply layer includes
a thin film portion thinned by the recess region, and
a thick film portion thicker than the thin film portion.

16. The nitride semiconductor device according to claim 1, wherein
the electron supply layer is a first electron supply layer,
a lower portion of the gate layer includes a recess region extending through the first electron supply layer and reaching the electron transit layer,
the nitride semiconductor device includes a second electron supply layer made of a nitride semiconductor having a band gap larger than that of the electron transit layer,
the second electron supply layer is provided to extend over both the recess region and the first electron supply layer,
the gate layer includes
a bottom surface in contact with an upper surface of the second electron supply layer, and
a protrusion protruding from the bottom surface toward the electron transit layer, and
the protrusion is disposed in the recess region and is in contact with the second electron supply layer.

17. The nitride semiconductor device according to claim 16, wherein the second electron supply layer is made of the same material as the first electron supply layer.

18. The nitride semiconductor device according to claim 15, wherein
each of the electron transit layer and the electron supply layer includes:
an active region where a two-dimensional electron gas is generated, and
an inactive region where the two-dimensional electron gas is less likely to be generated than in the active region,
the gate layer is formed to extend over both the active region and the inactive region, and
the recess region is provided between the source electrode and the drain electrode and is formed to extend over both the active region and the inactive region.

19. The nitride semiconductor device according to claim 1, further comprising:
an insulating passivation film covering the first gate electrode and the second gate electrode;
a gate wiring line formed on the passivation film; and
a gate via extending through the passivation film and configured to electrically connect the second gate electrode and the gate wiring line to each other.

20. The nitride semiconductor device according to claim 19, further comprising a gate plug embedded in the gate via.
